(19) United States
(12) Patent Application Publication
(10) Pub. No.: US 2006/0108592 A1
(43) Pub. Date: May 25, 2006

(54) Organic electroluminescent apparatus

(76) Inventors: Kazuki Nishimura, Osaka (JP); Haruhisa Hashimoto, Osaka (JP); Masahiro Iyori, Osaka (JP); Yuji Hamada, Ikoma-gun (JP)

Correspondence Address: MCDERMOTT WILL & EMERY LLP, 600 13TH STREET, N.W., WASHINGTON, DC, 20005-3096, US

(21) Appl. No.: 11/260,489

(22) Filed: Oct. 28, 2005

(30) Foreign Application Priority Data
Oct. 29, 2004 (JP) 2004-316528
Oct. 29, 2004 (JP) 2004-316530

(51) Int. Cl. H01L 51/52; H05B 33/02

(52) U.S. Cl. 257/89; 257/98; 257/E51.022; 313/504; 313/506; 313/112

(57) ABSTRACT

A red color filter layer is provided under an organic EL device. A green color filter layer, a blue color filter layer, and a region without a color filter layer are provided in this order under an organic EL device. Orange light from the organic EL device is transmitted through the red color filter layer, so that red color is obtained. White light from the organic EL device is transmitted through the green color filter layer and the blue color filter layer, so that green light and blue light are obtained. White light is obtained from the organic EL device. In this way, red light, green light, blue light, and white light are obtained.

### BACKGROUND OF THE INVENTION

1. Field of the Invention

The present invention relates to an organic electroluminescent apparatus.

2. Description of the Background Art

In recent years, as various kinds of information equipment have come to be used, there has been an increasing demand for flat panel display devices that can be used with less power consumption than generally used CRTs (Cathode Ray Tubes). Thin and lightweight organic electroluminescent (hereinafter abbreviated as “organic EL”) devices having high efficiency and low angular-field-of-view dependency have attracted attention as one type of such flat panel display devices, and displays using the organic EL devices have actively been developed.

The organic EL device is a self-light emitting device in which electrons and holes from an electron injection electrode and a hole injection electrode, respectively are injected to a light emitting portion, and the injected electrons and holes are recombined in the center of the light emitting portion, so that an organic molecule attains an excited state. Then, the organic molecule emits fluorescent light when it returns from the excited state to the ground state.

In the organic EL device, the color of fluorescence can be changed depending on the selected fluorescent material as a light emitting material, and therefore there have been growing expectations for its application to displays such as multi-color and full-color displays. The organic EL device can carry out surface-light emission at low voltage and therefore can serve as a back light for a liquid crystal display or the like. At the moment, applications of the organic EL devices to small size displays for example for digital cameras and mobile phones are in progress.

The organic EL device in general includes a hole injection electrode, a hole injection layer, a hole transport layer, a light emitting layer, an electron transport layer, an electron injection layer, and an electron injection electrode layered in this order on a substrate.

In the organic EL device described above, in order to carry out full-color display, organic EL devices that emit light in three primary colors, red, green, and blue must independently be provided. This complicates the manufacturing process.

There has been a suggested organic EL apparatus capable of implementing full-color display using a combination of a white light emitting device and three primary color filter layers each transmitting light in a single color, so that such complication of the manufacturing process can be prevented (see for example Japanese Patent Laid-Open No. H11-260562). The white light emitting device includes a blue light emitting material and an orange light emitting material, and white light is emitted by simultaneously emitting blue light by the blue light emitting material and orange light by the orange light emitting material.

The organic EL apparatus as described above including such a combination of the white light emitting element and the color filter layers may include the following arrangements.

One arrangement includes a white light emitting device and a plurality of color filter layers that each transmit light in a single color among three primary colors (hereinafter referred to as “first arrangement”). Another arrangement consists of the first arrangement and an additional area without a color filter layer for obtaining white light from the white light emitting device (hereinafter referred to as “second arrangement”). In an organic EL apparatus in the second arrangement, light in the area with no color filter layer is not attenuated. In this way, the luminous efficiency is better than that of an organic EL apparatus in the first arrangement and the power consumption can be reduced.

However, in organic EL apparatuses in the first and second arrangements described above, light from the white light emitting device is transmitted through the color filter layers to obtain light in the three primary colors and is greatly attenuated. Consequently, the luminous efficiency is lowered, and the power consumption is raised.

### SUMMARY OF THE INVENTION

It is an object of the invention to provide an organic electroluminescent apparatus that allows the luminous efficiency to be improved.

An organic electroluminescent apparatus according to one aspect of the invention includes a first organic electroluminescent device that generates light in a first color, a second organic electroluminescent device that generates light in a second color, a third organic electroluminescent device that generates light in a third color, a first color changing member that changes light in the first color generated by the first organic electroluminescent device into light in a fourth color, a second color changing member that changes light in the second color generated by the second organic electroluminescent device into light in a fifth color, and a third color changing member that changes light in the third color generated by the third organic electroluminescent device into light in a sixth color, and the first color and the fourth color are approximately the same.

In the organic electroluminescent apparatus, light in the first color generated by the first organic electroluminescent device is changed into light in the fourth color approximately the same as the first color by the first color changing member, light generated by the second organic electroluminescent device is changed into light in the fifth color by the second color changing member, light in the third color generated by the third organic electroluminescent device is changed into light in the sixth color by the third color changing member.

The light in the first color generated by the first organic electroluminescent device has higher emission intensity than light in the other colors in the wavelength range of light in the fourth color.

In this way, light in the fourth color having high emission intensity can be obtained by the first color changing member. Therefore, the luminous efficiency of the organic electroluminescent apparatus improves and the power consumption can be reduced.

The second color and the fifth color may approximately be the same. In this way, light in the second color generated by the second organic electroluminescent device has higher emission intensity in the wavelength range of light in the fifth color than light in the other colors.

In this way, light in the fifth color having high emission intensity can be obtained by the second color changing member. Therefore, the luminous efficiency of the organic electroluminescent apparatus improves and the power consumption can be more reduced.

The first color may be orange, the second color may be white, the third color may be white, the fourth color may be red, the fifth color may be green, and the sixth color may be blue. In this case, light in orange as the first color is changed into light in red as the fourth color, light in white as the second color is changed into light in green as the fifth color, and light in white as the third color is changed into light in blue as the sixth color.

In this way, the orange as the first color and the red as the fourth color are approximately the same, so that the luminous efficiency of the organic electroluminescent apparatus improves and the power consumption can be reduced.

The second and third organic electroluminescent devices emit light in the same color and have the same structure, so that the number of steps and time necessary for manufacturing the organic electroluminescent apparatus can be reduced.

When blue light and orange light complement each other to obtain white light, the second and third organic electroluminescent devices that generate white light have blue and orange light emitting layers. In this way, the orange light emitting layers in the first, second and third organic electroluminescent devices can be produced by common steps. Therefore, the number of steps and time necessary for manufacturing the organic electroluminescent apparatus can be reduced.

The first color may be orange, the second color may be orange, the third color may be white, the fourth color may be red, the fifth color may be green, and the sixth color may be blue. In this case, light in orange as the first color is changed into light in red as the fourth color, light in orange as the second color is changed into light in green as the fifth color, and light in white as the third color is changed into light in blue as the sixth color.

In this way, the orange as the first color and the red as the fourth color are approximately the same, so that the luminous efficiency of the organic electroluminescent apparatus improves and the power consumption can be reduced.

The first and second organic electroluminescent devices emit light in the same color and have the same structure, so that the number of steps and time necessary for manufacturing the organic electroluminescent apparatus can be reduced.

When blue light and orange light complement each other to obtain white light, the third organic electroluminescent device that emits white light has blue and orange light emitting layers. In this way, the orange light emitting layers in the first, second, and third organic electroluminescent devices can be produced by common steps. Therefore, the number of steps and time necessary for manufacturing the organic electroluminescent apparatus can be reduced.

The first color may be blue, the second color may be white, the third color may be white, the fourth color may be blue, the fifth color may be green, and the sixth color may be red. In this case, light in blue as the first color is changed into light in blue as the fourth color, light in white as the second color is changed into light in green as the fifth color, and light in white as the third color is changed into light in red as the sixth color.

In this way, the blue as the first color and the blue as the fourth color are approximately the same, so that the luminous efficiency of the organic electroluminescent apparatus improves and the power consumption can be reduced.

The second and third organic electroluminescent devices emit light in the same color and have the same structure, so that the number of steps and time necessary for manufacturing the organic electroluminescent apparatus can be reduced.

When blue light and orange light complement each other to obtain white light, the second and third organic electroluminescent devices that generate white light include blue and orange light emitting layers. In this way, the blue light emitting layers in the first, second, and third organic electroluminescent devices can be produced by common steps. Therefore, the number of steps and time necessary for manufacturing the organic electroluminescent apparatus can be reduced.

The first color may be blue, the second color may be blue, the third color may be white, the fourth color may be blue, the fifth color may be green, and the sixth color may be red. In this case, light in blue as the first color is changed into light in blue as the fourth color, light in blue as the second color is changed into light in green as the fifth color, and light in white as the third color is changed into red as the sixth color.

In this way, the blue as the first color and the blue as the fourth color are approximately the same, so that the luminous efficiency of the organic electroluminescent apparatus improves and the power consumption can be reduced.

The first and second organic electroluminescent devices generate light in the same color and have the same structure, so that the number of steps and time necessary for manufacturing the organic electroluminescent apparatus can be reduced.

When blue light and orange light complement each other to obtain white light, the third organic electroluminescent device that generates white light includes blue and orange light emitting layers. Therefore, the blue light emitting layers in the first, second, and third organic electroluminescent devices can be produced by common steps. In this way, the number of steps and time necessary for manufacturing the organic electroluminescent apparatus can be reduced.

The first color may be orange, the second color may be blue, the third color may be blue, the fourth color may be red, the fifth color may be blue, and the sixth color may be green. In this case, light in orange as the first color is changed into light in red as the fourth color, light in blue as the second color is changed into light in blue as the fifth color, and light in blue as the third color is changed into light in green as the sixth color.

In this way, the orange as the first color and the red as the fourth color are approximately the same, and the blue as the second color and the blue as the fifth color are approximately the same, so that the luminous efficiency of the organic electroluminescent apparatus improves and the power consumption can be further reduced.

The second and third organic electroluminescent devices generate light in the same color and have the same structure, and therefore the number of steps and time necessary for manufacturing the organic electroluminescent apparatus can be reduced.

The first color may be orange, the second color may be blue, the third color may be orange, the fourth color may be red, the fifth color may be blue, and the sixth color may be green. In this case, light in orange as the first color is changed into light in red as the fourth color, light in blue as the second color is changed into light in blue as the fifth color, and light in orange as the third color is changed into light in green as the sixth color.

In this way, the orange as the first color and the red as the fourth color are approximately the same, and the blue as the second color and the blue as the fifth color are approximately the same, so that the luminous efficiency of the organic electroluminescent apparatus improves and the power consumption can be reduced.

The first and third organic electroluminescent devices generate light in the same color and have the same structure, and therefore the number of steps and time necessary for manufacturing the organic electroluminescent apparatus can be reduced.

The first color may be orange, the second color may be blue, the third color may be white, the fourth color may be red, the fifth color may be blue, and the sixth color may be green. In this way, light in orange as the first color is changed into light in red as the fourth color, light in blue as the second color is changed into light in blue as the fifth color, and light in white as the third color is changed into light in green as the sixth color.

In this way, the orange as the first color and the red as the fourth color are approximately the same, and the blue as the second color and the blue as the fifth color are approximately the same, so that the luminous efficiency of the organic electroluminescent apparatus improves and the power consumption can be reduced.

When blue light and orange light are complemented to obtain white light, the third organic electroluminescent device that generates white light has blue and orange light emitting layers. Therefore, the orange light emitting layers in the first and third organic electroluminescent devices can be produced by common steps. The blue light emitting layers in the second and third organic electroluminescent devices can be produced by common steps. Therefore, the number of steps and time necessary for manufacturing the organic electroluminescent apparatus can be reduced.

The apparatus may further include a substrate, the first, second, and third organic electroluminescent devices may be formed on the substrate, and the first, second, and third color changing members may be formed on the first, second, and third organic electroluminescent devices, respectively. In this way, a top emission type organic electroluminescent apparatus can be implemented.

The apparatus may further include a transparent substrate, and the first, second, and third color changing members may be provided between the transparent substrate and the first, second, and third organic electroluminescent devices, respectively. In this way, a bottom emission type organic electroluminescent apparatus can be implemented.

An organic electroluminescent apparatus according to another aspect of the invention includes a first organic electroluminescent device that generates light in a first color, a second organic electroluminescent device that generates light in a second color, a third organic electroluminescent device that generates light in a third color, and a fourth color changing member that changes light in the second color generated by the second organic electroluminescent device into light in a seventh color. Light generated by at least one of the first and third organic electroluminescent devices is externally output without being passed through the color changing member.

In the organic electroluminescent apparatus, light generated by at least one of the first and third organic electroluminescent devices does not pass the color changing member, and therefore the luminous efficiency for light in at least one color improves.

The organic electroluminescent apparatus may further include a fifth color changing member that changes light in the third color generated by the third organic electroluminescent device into light in an eighth color, and light generated by the first organic electroluminescent device may be externally output without being passed through any of the color changing members.

In this case, light generated by the first organic electroluminescent device does not pass the color changing member, so that the luminous efficiency for light in the first color improves.

The organic electroluminescent apparatus may further include a sixth color changing member that changes light in the first color generated by the first organic electroluminescent device into light in a ninth color, and light generated by the third organic electroluminescent device may be externally output without being passed through any of the color changing members.

In this case, light generated by the third organic electroluminescent device does not pass any of the color changing members, so that the luminous efficiency for light in the third color improves.

Light generated by the first and third organic electroluminescent devices may be externally output without being passed through any one of the color changing members. In this case, light generated by the first and third organic electroluminescent devices does not pass any one of the color changing members, so that the luminous efficiency for light in the first and third colors improves.

The organic electroluminescent apparatus may further include a substrate, the first to third organic electroluminescent devices may be formed on the substrate, and the color changing member may be provided on at least one of the first and third organic electroluminescent devices. In this way, a top emission type organic electroluminescent apparatus can be implemented.

The organic electroluminescent apparatus may further include a substrate, and the color changing member may be provided between the substrate and at least one of the first and third organic electroluminescent devices. In this way, a bottom emission type organic electroluminescent apparatus can be implemented.

These and other objects and advantages of the present invention will become clear from the following description with reference to the accompanying drawings.

### BRIEF DESCRIPTION OF THE DRAWINGS

FIG. 1 is top views each showing the arrangement of light emitting regions for one pixel in an organic EL apparatus according to a first embodiment of the invention;

FIG. 2 is a sectional view of an example of the structure of an organic EL apparatus according to the first embodiment;

FIG. 3 shows an example of an absorption spectra for a red color filter layer, a green color filter layer, and a blue color filter layer;

FIG. 4 shows the relation between two organic EL devices and the color filter layers in FIG. 2;

FIGS. 5 and 6 show the structures of organic EL apparatuses based on a plurality of modes according to the first embodiment;

FIG. 7 is a sectional view of an example of the structure of an organic EL apparatus according to a second embodiment of the invention;

FIGS. 8 and 9 show the structures of organic EL apparatuses based on a plurality of modes according to the second embodiment;

FIG. 10 shows the structures of organic EL apparatuses based on a plurality of modes according to a third embodiment of the invention;

FIG. 11 is a sectional view of an example of the structure of an organic EL apparatus according to a fourth embodiment of the invention;

FIGS. 12 and 13 show the structures of organic EL apparatuses based on the modes in Table 1;

FIG. 14 is a sectional view of an example of the structure of an organic EL apparatus according to a fifth embodiment of the invention;

FIGS. 15 and 16 show the structures of organic EL apparatuses based on the modes in Table 1; and

FIG. 17 shows the structures of organic EL apparatuses based on modes in Table 2.

### DESCRIPTION OF THE PREFERRED EMBODIMENTS

Now, an organic electroluminescent (hereinafter referred to as “organic EL”) apparatus according to embodiments of the invention will be described in conjunction with the accompanying drawings.

### First Embodiment

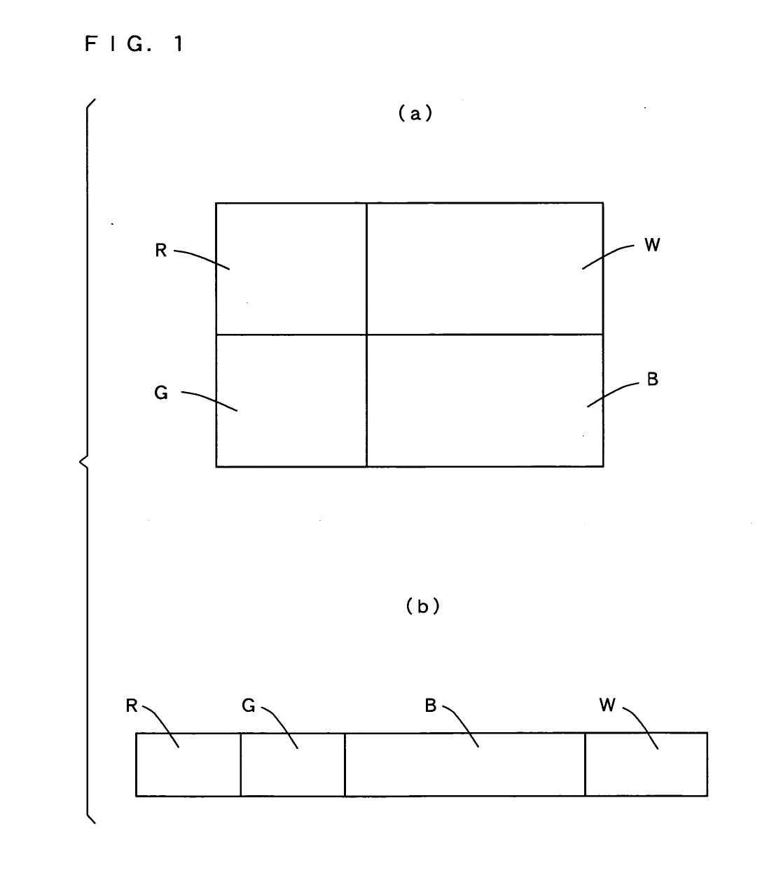

FIGS. 1(a) and 1(b) are top views each showing the arrangement of the light emitting region of a pixel in an organic EL apparatus according to a first embodiment of the invention. Note that in FIGS. 1(a) and 1(b), the region that emits red light is denoted by R, the region that emits green light by G, the region that emits blue light by B, and the region that emits white light by W.

As shown in FIG. 1(a), the regions R, G, B, and W are for example provided in the upper left, lower left, lower right, and upper right regions, respectively that are produced by dividing a square into four.

As shown in FIG. 1(b), the regions R, G, B, and W may be aligned in this order.

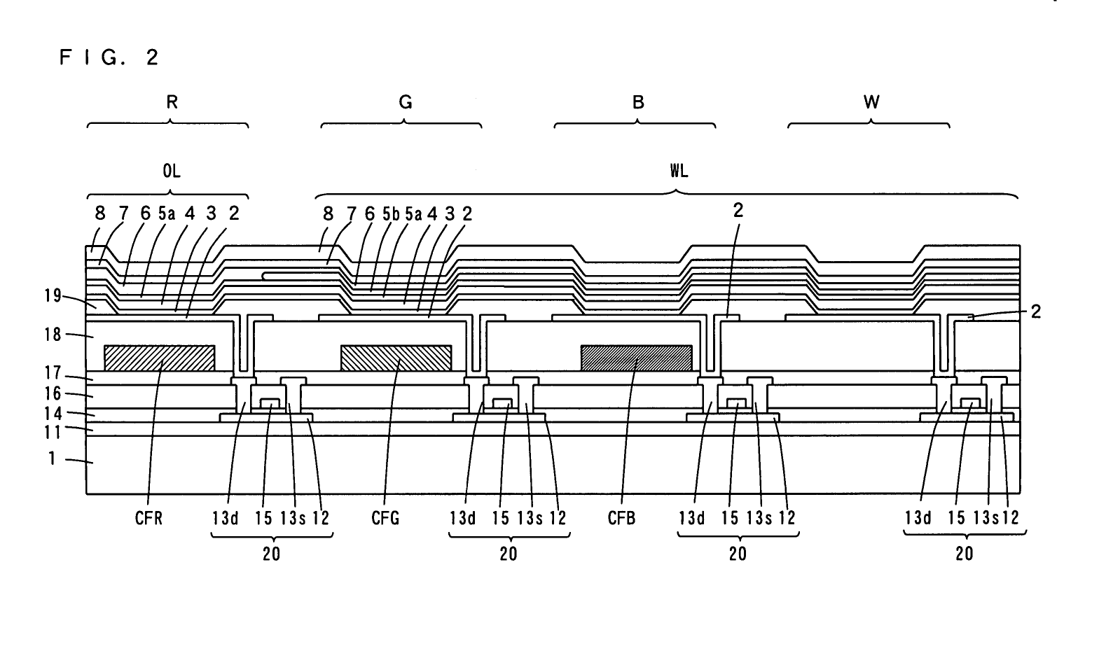

FIG. 2 is a sectional view of an example of an arrangement of an organic EL apparatus according to the first embodiment.

The example in FIG. 2 and following other examples of organic EL apparatuses shown in sectional views correspond to the top view in FIG. 1(b). Therefore, the organic EL apparatus according to the embodiment can emit red light, green light, blue light, and white light in this order from the left.

In FIG. 2, an organic EL device OL that emits orange light and an organic EL device WL that emits white light are provided from the left.

In the above-described arrangement, orange light from the organic EL device OL is transmitted through a red color filter layer to obtain red light. White light from the organic EL device WL is transmitted through prescribed color filter layers to obtain green light and blue light. White light is obtained from the organic EL device WL. In this case, there is no color filter layer. In this way, red light, green light, blue light, and white light are obtained. Now, the process will be described in detail.

As shown in FIG. 2, a layered film 11 having for example a silicon oxide (SiO₂) layer and a silicon nitride (SiNₓ) layer is formed on a transparent substrate 1 of glass, plastic or the like.

A plurality of TFTs (Thin Film Transistors) 20 are formed on the layered film 11 corresponding to the regions R, G, B, and W in FIG. 1(b). The TFTs 20 each include a channel region 12, a drain electrode 13d, a source electrode 13s, a gate oxide film 14, and a gate electrode 15.

The channel region 12 formed of a polysilicon layer or the like is formed on a part of the layered film 11. The drain electrode 13d and the source electrode 13s are formed on the channel region 12. The gate oxide film 14 is formed on the channel region 12. The gate electrode 15 is formed on the gate oxide film 14.

The drain electrodes 13d of the TFTs 20 are provided corresponding to the regions R, G, B, and W on a one-to-one basis. The source electrode 13s of each of the TFTs 20 is connected to a hole injection electrode 2 (that will be described) and thus connected to a power supply line (not shown).

A first interlayer insulating film 16 is formed on the gate oxide film 14 to cover the gate electrode 15(a) second interlayer insulating film 17 is formed on the first interlayer insulating film 16 to cover the drain electrode 13d and the source electrode 13s. The gate electrode 15 is connected to an electrode (not shown).

Note that the gate oxide film 14 has a layered structure having for example a silicon nitride layer and a silicon oxide layer. The first interlayer insulating film 16 has a layered structure having for example a silicon oxide layer and a silicon nitride layer, and the second interlayer insulating film 17 is for example made of silicon nitride.

In the example in FIG. 2, a red color filter layer CFR, a green color filter layer CFG, and a blue color filter layer CFB are formed on the second interlayer insulating film 17 in the positions of the regions R, G, and B, respectively. The red color filter layer CFR transmits light in a red wavelength region. The green color filter layer CFG transmits light in a green wavelength region. The blue color filter layer CFB transmits light in a blue wavelength region.

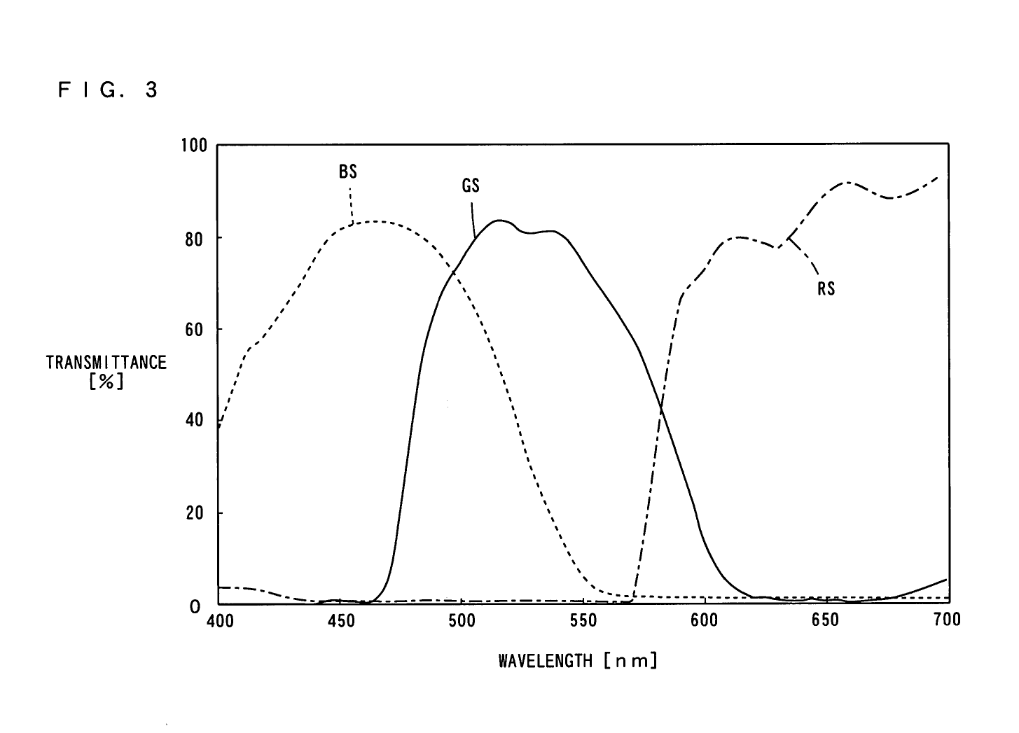

FIG. 3 shows an example of the absorption spectra of the red color filter layer CFR, the green color filter layer CFG, and the blue color filter layer CFB. In FIG. 3, the ordinate represents the transmittance of light with respect to the color filter layers, and the abscissa represents the wavelength of light transmitted through the color filter layers.

In FIG. 3, the absorption spectrum of the red color filter layer CFR is represented by the chain-dotted line RS. In this case, the red color filter layer CFR transmits light having a wavelength of about 570 nm or more, and at least 80% of light having a wavelength of about 600 nm or more.

The absorption spectrum of the green color filter layer CFG is represented by the solid line GS. In this case, the green color filter layer CFG transmits light having a wavelength about in the range from 470 nm to 600 nm, and about 80% of light having a wavelength about in the range from 510 nm to 550 nm.

The absorption spectrum of the blue color filter layer CFB is represented by the dotted line BS. In this case, the blue color filter layer CFB transmits light having a wavelength of about 550 nm or less, and about 80% of light having a wavelength about in the range from 440 nm to 480 nm.

These color filter layers are each made of a transparent material such as glass and plastic. A. CCM (Color-Changing Medium) may be used for each of the color filter layers, or a transparent material such as glass and plastic and a CCM may both be used.

A first planarization layer 18 of acrylic resin or the like is formed to continuously extend along the regions R, G, B, and W on the second interlayer insulating film 17 to cover the red color filter layer CFR, the green color filter layer CFG, and the blue color filter layer CFB. The organic EL device OL is formed in the position corresponding to the region R on the first planarization layer 18, and the organic EL device WL is formed in the position corresponding to all the other regions G, B, and W on the first planarization layer 18.

More specifically, according to the embodiment, the red color filter layer CFR is provided under the organic EL device OL. Under the organic EL device WL, the green color filter layer CFG, the blue color filter layer CFB, and the region with no color filter layer are provided in this order. In this way, red light, green light, blue light, and white light having high color purity can be obtained.

Now, the structure of the organic EL device OL and the organic EL device WL provided on the first planarization layer 18 will be described.

The organic EL device OL includes a hole injection electrode 2, a hole injection layer 3, a hole transport layer 4, an orange light emitting layer 5a that emits orange light, an electron transport layer 6, an electron injection layer 7, and an electron injection electrode 8 in this order.

The organic EL device WL includes a hole injection electrode 2, a hole injection layer 3, a hole transport layer 4, an orange light emitting layer 5a that emits orange light, a blue light emitting layer 5b that emits blue light, an electron transport layer 6, an electron injection layer 7, and an electron injection electrode 8 in this order.

The hole injection electrodes 2 are formed on the first planarization layer 18 in the positions corresponding to the regions R, G, B, and W, and an insulating, second planarization layer 19 is formed to cover the hole injection electrodes 2 between the regions R, G, B, and W. The hole injection electrodes 2 are for example made of a transparent conductive film such as indium-tin-oxide (ITO) as thick as 100 nm.

The hole injection layer 3 is formed on the entire region to cover the hole injection electrodes 2 and the second planarization layer 19. The hole injection layer 3 is for example made of a carbon fluoride (CFx) film as thick as 1 nm.

The hole transport layer 4 and then the orange light emitting layer 5a are formed on the hole injection layer 3. The hole transport layer 4 is for example as thick as 110 nm and made for example of a triarylamine derivative as expressed by the following Formula (1):

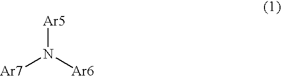

In Formula (1), Ar5 to Ar7 represent aromatic substituents, and they may be the same or different from one another.

In Formula (1), the carbon number of each of the aromatic substituents Ar5 to Ar7 is preferably not more than 16. In this way, the molecular weight of the triarylamine derivative is small, which allows vacuum deposition to be readily carried out in the process of producing the hole transport layer 4.

The triarylamine derivative used for the hole transport layer 4 is for example a benzidine derivative expressed by the following Formula (2):

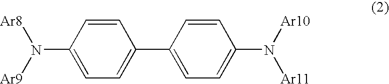

In Formula (2), Ar8 to Ar11 represent aromatic substituents, and they may be the same or different from one another. The aromatic substituents Ar8 to Ar11 in Formula (2) may be for example a phenyl group, a 3-methylphenyl group, a 1-naphthyl group, a 2-naphthyl group, a 1,1′-biphenyl-4-yl group, a 9-anthryl group, a 2-thienyl group, a 2-pyridyl group, or a 3-pyridyl group.

In Formula (2), the carbon number of each of the aromatic substituents Ar8 to Ar11 is preferably not more than 16. In this way, the molecular weight of the benzidine derivative is small, which allows vacuum deposition to be readily carried out in the process of producing the hole transport layer 4.

According to the embodiment, the hole transport layer 4 is made of N,N′-Di(1-naphthyl)-N,N′-diphenyl-benzidine) (hereinafter abbreviated as “NPB”) expressed by the following Formula (3).

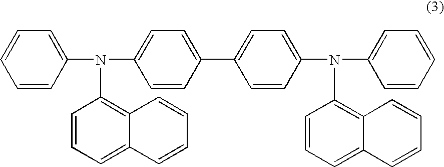

The triarylamine derivative used for the hole transport layer 4 may be a triphenylamine derivative expressed by the following Formula (4):

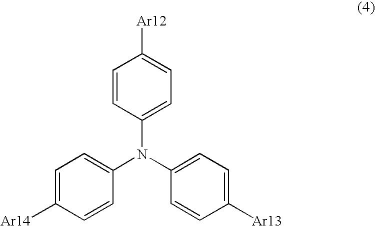

In Formula (4), Ar12 to Ar14 represent aromatic substituents, and they may be the same or different from one another. The aromatic substituents Ar12 to Ar14 in Formula (4) may be for example a phenyl group, a 3-methylphenyl group, a 4-tert-butylphenyl group, a 1-naphthyl group, a 2-naphthyl group, a 1,1′-biphenyl-4-yl group, a 9-anthryl group, a 2-thienyl group, a 2-pyridyl group, or a 3-pyridyl group.

The carbon number of each of the aromatic substituents Ar12 to Ar14 in Formula (4) is preferably not more than 16. In this way, the molecular weight of the triphenylamine derivative is small, which allows vacuum deposition to be readily carried out in the process of producing the hole transport layer 4.

The orange light emitting layer 5a has a host material doped with a first dopant and a second dopant. Note that the orange light emitting layer 5a is for example as thick as 30 nm.

The host material for the orange light emitting layer 5a may be for example NPB, the same material as that of the hole transport layer 4.

The first dopant of the orange light emitting layer 5a may be for example a tetracene derivative expressed by the following Formula (5).

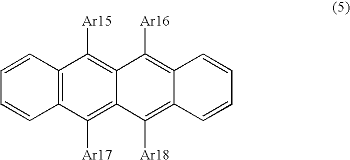

In Formula (5), Ar115 to Ar18 each represent any of a hydrogen atom, a halogen atom, an aliphatic substituent and an aromatic substituent, and they may be the same or different from one another. As aliphatic substituents, Ar15 to Ar18 in Formula (5) may be a methyl group, an ethyl group, a 1-propyl group, a 2-propyl group, or a tert-butyl group. As aromatic substituents, Ar13 to Ar16 in Formula (5) may be a phenyl group, a 3-methylphenyl group, a 4-tert-butylphenyl group, a 1-naphtyl group, a 2-naphtyl group, a 4-tert-butyl-1-naphtyl group, a 1,1′-biphenyl-4-yl group, a 9-anthryl group, a 2-thienyl group, 2-pyridyl group, or a 3-pyridyl group.

The carbon number of each of Ar15 to Ar18 as the aliphatic substituents in Formula (5) is preferably not more than four, and the carbon number of each of Ar15 to Ar18 as the aromatic substituents in Formula (5) is preferably not more than 16. In this way, the molecular weight of the tetracene derivative is small, which allows vacuum deposition to be readily carried out in the process of producing the orange light emitting layer 5a.

According to the embodiment, the first dopant for the orange light emitting layer 5a is a 5,12(b)is(4-tert-butylphenyl)-naphthacene (abbreviated as “tBuDPN”) expressed by the following Formula (6). The orange light emitting layer 5a is doped with the first dopant so that the dopant accounts for 20% by weight.

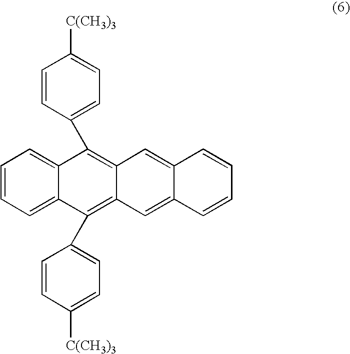

The second dopant of the orange light emitting layer 5a may be for example a 5,12(b)is(4-(6-methylbenzothiazol-2-yl)phenyl)-6,11-diphenylnaphthacene) (abbreviated as “DBzR”) expressed by the following Formula (7). The orange light emitting layer 5a is doped with the second dopant so that the second dopant accounts for 3% by weight.

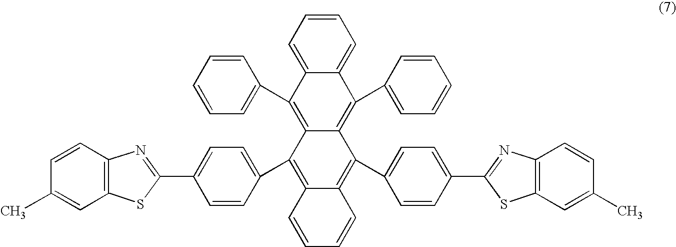

The second dopant of the orange light emitting layer 5a emits light, and the first dopant serves to aid the second dopant in emitting light by accelerating the energy movement from the host material to the second dopant. In this way, the orange light emitting layer 5a generates orange light having a peak wavelength larger than 500 nm and smaller than 650 nm.

Then, a blue light emitting layer 5b is formed on the orange light emitting layer 5a. A mask is formed on the orange light emitting layer 5a in the position corresponding to the region R, and the blue light emitting layer 5b is formed on the orange light emitting layer 5a in the position corresponding to the regions G, B, and W. In this way, the organic EL device OL has the orange light emitting layer 5a, and the organic EL device WL has a layered structure including the orange light emitting layer 5a and the blue light emitting layer 5b.

The blue light emitting layer 5b has a host material doped with first and second dopants. Note that the blue light emitting layer 5b is for example as thick as 40 nm.

The host material for the blue light emitting layer 5b may be for example a tert-butyl substituted dinaphthylanthracene (abbreviated as “TBADN”) expressed by the following Formula (8).

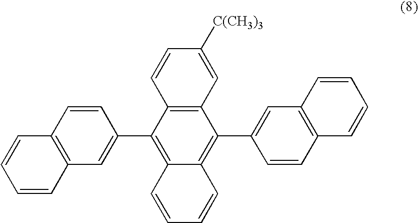

The first dopant of the blue light emitting layer 5b may be for example NPB, the same material as that of the hole transport layer 4. The blue light emitting layer 5b is doped with the first dopant so that the first dopant accounts for 10% by weight.

The second dopant for the blue light emitting layer 5b may be for example 1,4,7,10-Tetra-tert-butylPerylene (abbreviated as “TBP”) expressed by the following Formula (9). The blue light emitting layer 5b is doped with the second dopant so that the second dopant accounts for 2.5% by weight.

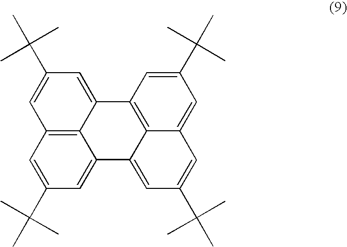

The second dopant of the blue light emitting layer 5b emits light and the first dopant serves to aid the second dopant in emitting light by accelerating the carrier transport. In this way, the blue light emitting layer 5b emits light having a peak wavelength larger than 400 nm and smaller than 500 nm.

Now, an electron transport layer 6, an electron injection layer 7, and an electron injection electrode 8 are formed on the orange light emitting layer 5a and the blue light emitting layer 5b.

The electron transport layer 6 is about as thick as 10 nm and made of Tris (8-hydroxyquinolinato)aluminum (abbreviated as “Alq”) expressed by the following Formula (10):

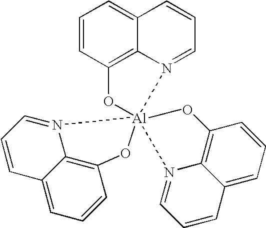

The electron injection layer 7 is for example as thick as 1 nm and made of lithium fluoride (LiF), and the electron injection electrode 8 is for example as thick as 200 nm and made of aluminum (Al).

Note that although not shown in FIG. 2, a protection layer may be formed on the electron injection electrode 8.

As in the foregoing, according to the embodiment, the red color filter layer CFR is provided in the region to form the organic EL device OL (region R) that emits orange light. The green color filter layer CFG and the blue color filter layer CFB are provided in a part of the regions (regions G and B) of the organic EL device WL that emits white light.

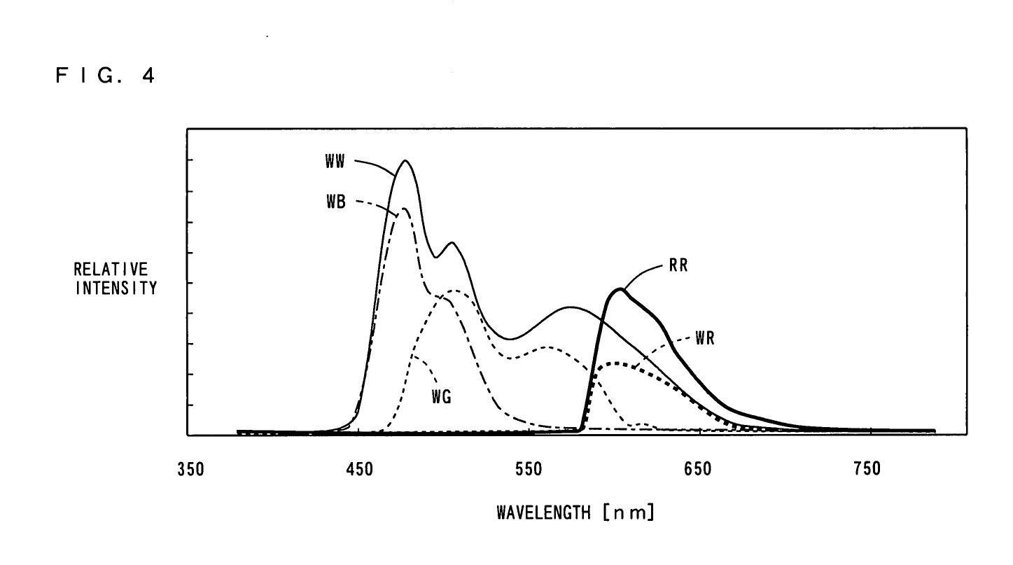

FIG. 4 shows relations between the two organic EL devices OL and WL in FIG. 2 and the color filter layers CFR, CRG, and CFB. In FIG. 4, the ordinate represents the relative intensity of light, and the abscissa represents the wavelength of light.

In FIG. 4, the emission spectrum of white light at the organic EL device WL is indicated by the solid line WW. As described above, the organic EL device WL includes the orange light emitting layer 5a and the blue light emitting layer 5b. In this way, the emission spectrum of the organic EL device WL has peaks at wavelengths of about 460 nm, 500 nm and 580 nm.

The emission spectrum of blue light obtained as white light from the organic EL device WL passes through the blue color filter layer CFB is indicated by the chain-dotted line WB. As shown in FIG. 4, the emission spectrum of blue light obtained as white light passes through the blue color filter layer CFB has a peak at a wavelength of about 460 nm.

The emission spectrum of green light obtained as white light from the organic EL device WL passes through the green color filter layer CFG is denoted by the dotted line WG.

As shown in FIG. 4, the emission spectrum of green light obtained as white light passes through the green color filter layer CFG has peaks at wavelengths of about 500 nm and 580 nm.

The emission spectrum of red light obtained as orange light from the organic EL device OL passes through the red color filter layer CFR is denoted by the bold line RR. As shown in FIG. 4, the emission spectrum of red light obtained through the red color filter layer CFR has a peak at a wavelength of about 600 nm. Note that the emission spectrum of the organic EL device OL is omitted.

Now, for the purpose of comparison, assume that white light from the organic EL device WL passes through the red color filter layer CFR. In this case, red light is obtained as white light from the organic EL device WL passes through the red color filter layer CFR. The emission spectrum of the red light is denoted by the bold dotted line WR. As shown in FIG. 4, the emission spectrum of the red light obtained as white light passes through the red color filter layer CFR has a peak at a wavelength of about 600 nm.

As shown in FIG. 4, the relative intensity of the red light based on the white light is smaller than the relative intensity of the red light based on the orange light. This is because the emission spectrum of the white light from organic EL device WL is small in a wavelength region around 600 nm as indicated by the solid line WW in FIG. 4. Stated differently, the orange light from the organic EL device OL has higher emission intensity in the wavelength range of the red light than that of the white light from the organic EL device WL.

Note that the wavelength range of the red light is for example from about 600 nm to about 780 nm. In the following description, the wavelength range of green light is for example from about 500 nm to about 600 nm, and the wavelength range of blue light is from about 380 nm to about 500 nm.

According to the embodiment, the orange light emitted from the organic EL device OL is passed through the red color filter layer CFR, so that the red light having high emission intensity is obtained. In this way, the luminous efficiency of the organic EL apparatus improves and the power consumption can be reduced.

The organic EL device WL has a common structure for the regions G, B, and W, so that the number of steps and time necessary for manufacturing the organic EL apparatus can be reduced.

In addition, the orange light emitting layers 5a in the organic EL devices WL and OL can be formed by common steps. In this way, the number of steps and time necessary for manufacturing the organic EL apparatus can be reduced.

As described above, according to the embodiment, red light, green light, and blue light are obtained through the red, green, and blue color filter layers CFR, CRG, and CFB, respectively, so that red light, green light, and blue light having high color purity can be provided.

Now, other examples of the organic EL apparatus will be described. Among the following organic EL apparatuses, different combinations of organic EL devices are employed. Hereinafter, a combination of a plurality of organic EL devices will be referred to as “mode.”

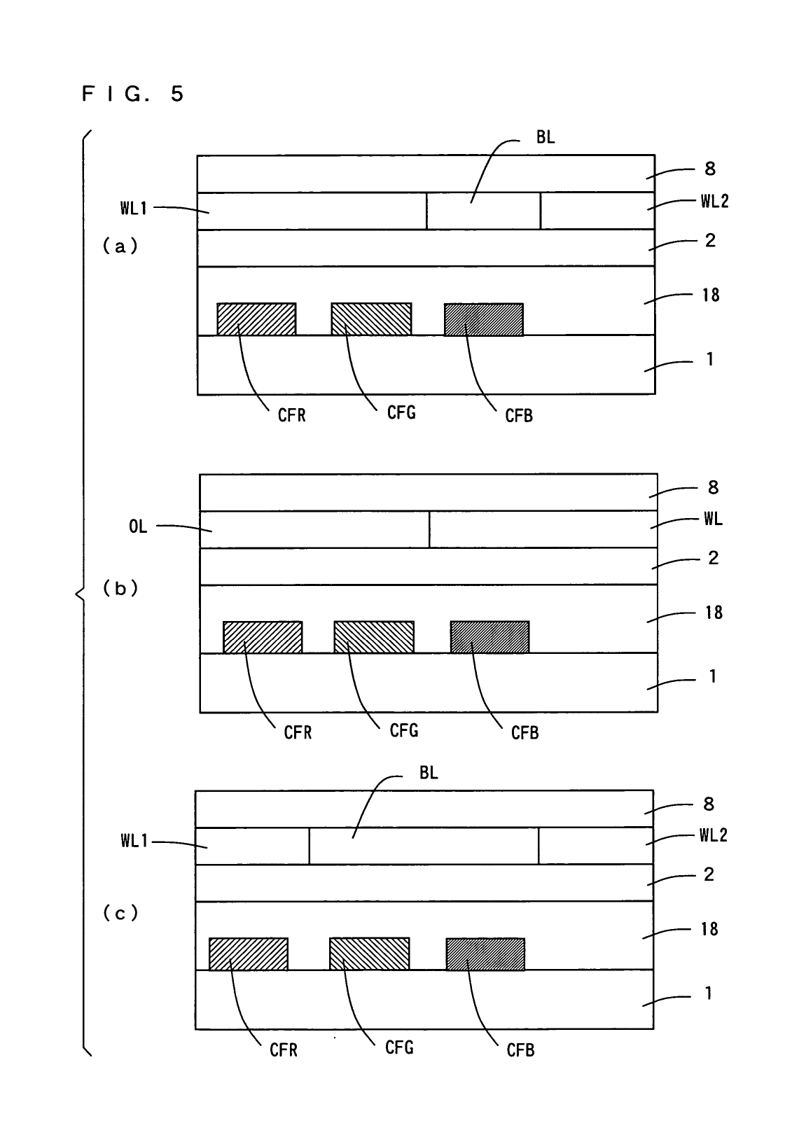

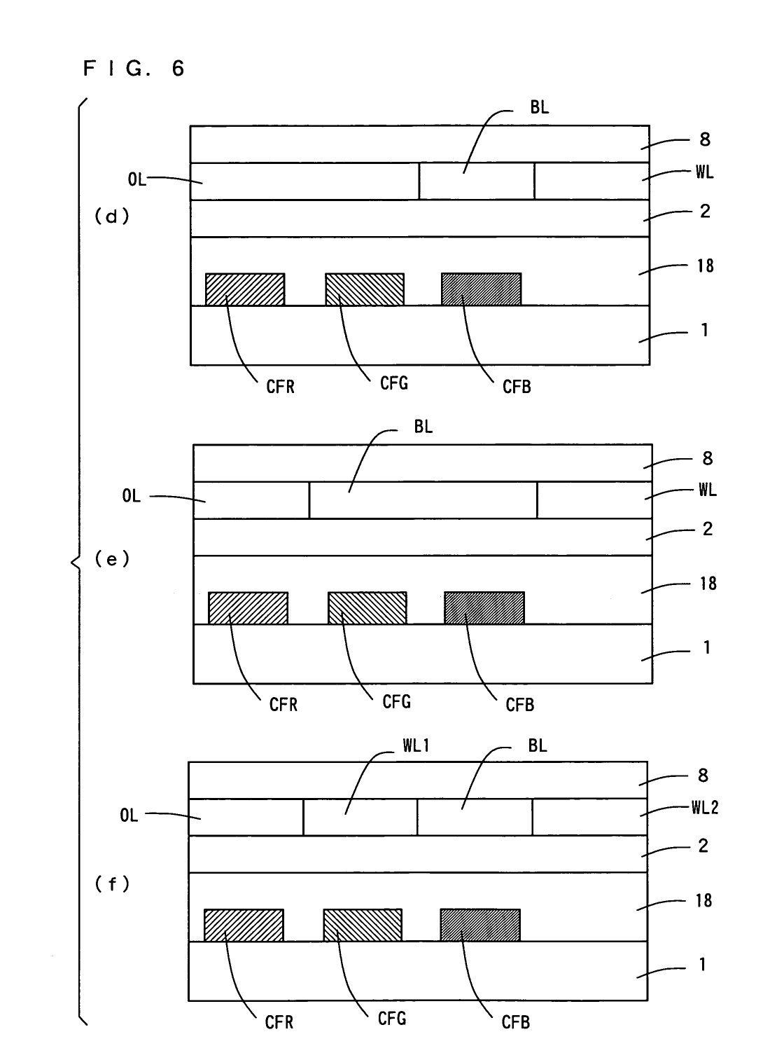

FIGS. 5(a) to 5(c) and 6(d) to 6(f) show the structure of organic EL apparatuses based on a plurality of modes according to the first embodiment. Note that in connection with FIG. 2, the structure of the organic EL apparatus according to the embodiment has been described in detail and therefore the organic EL apparatuses based on various modes will briefly be described in conjunction with FIGS. 5(a) to 5(c) and 6(d) to 6(f).

Note that according to the embodiment, the mode of the organic EL apparatus in FIG. 2 is referred to as “first mode” (Ro-GwBwWw). More specifically, in the organic EL apparatus based on the first mode, red light can be obtained based on orange light from the organic EL device OL, white light can be obtained by the organic EL device WL, and green light and blue light can be obtained based on white light from the organic EL device WL.

FIG. 5(a) shows the structure of an organic EL apparatus based on a second mode (RwGw-Bb-Ww).

In the organic EL apparatus based on the second mode, red light and green light can be obtained based on white light from a first organic EL device WL1, blue light can be obtained from an organic EL device BL that emits blue light, and white light can be obtained from a second organic EL device WL2. Note that the structure of the organic EL device BL is the same as that of the organic EL device WL except that no orange light emitting layer 5a is provided.

As shown in FIG. 5(a), the first organic EL device WL1 is formed on a hole injection electrode 2 in the position corresponding to the regions R and G in FIG. 1(b). Under the first organic EL device WL1, a red color filter layers CFR and a green color filter layer CFG are provided side by side in the positions corresponding to the regions R and G.

The organic EL device BL is formed on the hole injection electrode 2 in the position corresponding to the region B in FIG. 1(b). A blue color filter layer CFB is provided under the organic EL device BL. The second organic EL device WL2 is formed in the position corresponding to the region W in FIG. 1(b).

In the organic EL apparatus in FIG. 5(a), white light from the first organic EL device WL1 is transmitted through the red color filter layer CFR and the green color filter layer CFG, so that red light and green light can be obtained.

Blue light from the organic EL device BL is transmitted through the blue color filter layer CFB, so that blue light can be obtained. White light can be obtained from the second organic EL device WL2.

In this case, the blue light from the organic EL device BL has high emission intensity in the wavelength range of the blue light than the white light from the organic EL devices WL1 and WL2. Therefore, blue light having higher emission intensity than the blue color filter layer CFB can be obtained. In this way, the luminous efficiency of the organic EL apparatus improves and the power consumption can be reduced.

In addition, the organic EL device WL1 has a common structure for the regions R and G, and therefore the number of steps and time necessary for manufacturing the organic EL apparatus can be reduced.

The blue light emitting layers 5b in the organic EL devices WL1(b)L and WL2 can be formed by common steps, so that the number of steps and time necessary for manufacturing the organic EL apparatus can be further reduced.

FIG. 5(b) shows the structure of an organic EL apparatus based on a third mode (RoGo-BwWw).

In the organic EL apparatus based on the third mode, red light and green light can be obtained based on orange light from an organic EL device OL, and blue light and white light can be obtained based on white light from an organic EL device WL.

As shown in FIG. 5(b), the organic EL device OL is formed on a hole injection electrode 2 in the position corresponding to the regions R and G in FIG. 1(b). Under the organic EL device OL, a red color filter layer CFR and a green color filter layer CFG are provided side by side in the positions corresponding to the regions R and G.

The organic EL device WL is formed on the hole injection electrode 2 in the position corresponding to the regions B and W in FIG. 1(b). A blue color filter layer CFB is provided under the organic EL device WL in the position corresponding to the region B.

In the organic EL apparatus shown in FIG. 5(b), orange light from the organic EL device OL is transmitted through the red color filter layer CFR and the green color filter layer CFG, so that red light and green light can be obtained. White light from the organic EL device WL is transmitted through the blue color filter layer CFB, so that blue light can be obtained, while white light can be obtained from the organic EL device WL.

The orange light from the organic EL device OL has higher emission intensity in the range of the red light wavelength than that of the white light from the organic EL device WL. Therefore, red light having high emission intensity can be obtained by the red color filter layer CFR. In this way, the luminous efficiency of the organic EL apparatus improves and the power consumption can be reduced.

The organic EL device OL has a common structure for the regions R and G, and the organic EL device WL has a common structure for the regions B and W, so that the number of steps and time necessary for manufacturing the organic EL apparatus can be reduced.

The orange light emitting layers 5a in the organic EL devices OL and WL can be formed by common steps. In this way, the number of steps and time necessary for manufacturing the organic EL apparatus can be reduced.

FIG. 5(c) shows the structure of an organic EL apparatus based on a fourth mode (Rw-GbBb-Ww).

According to the organic EL apparatus based on the fourth mode, red light can be obtained based on white light from a first organic EL device WL1, green light and blue light can be obtained based on blue light from an organic EL device BL, and white light can be obtained from a second organic EL device WL2.

As shown in FIG. 5(c), the first organic EL device WL1 is formed on a hole injection electrode 2 in the position corresponding to the region R in FIG. 1(b). A red color filter layer CFR is provided under the first organic EL device WL1.

The organic EL device BL is formed on the hole injection electrode 2 in the position corresponding to the regions G and B in FIG. 1(b). A green color filter layer CFG and a blue color filter layer CFB are provided side by side under the organic EL device BL in the positions corresponding to the regions G and B in FIG. 1(b).

The second organic EL device WL2 is formed on the hole injection electrode 2 in the position corresponding to the region W in FIG. 1(b).

In the organic EL apparatus shown in FIG. 5(c), white light from the first organic EL device WL1 is transmitted through the red color filter layer CFR, so that red light can be obtained. Blue light from the organic EL device BL passes through the green color filter layer CFG and the blue color filter layer CFB, so that green light and blue light can be obtained. In addition, white light can be obtained from the second organic EL device WL2.

The blue light from the organic EL device BL has higher emission intensity in the wavelength ranges of the green light and blue light than the white light from the organic EL devices WL1 and WL2. Therefore, blue light having high emission intensity can be obtained by the blue color filter layer CFB. In this way, the luminous efficiency of the organic EL apparatus improves and the power consumption can be further reduced.

The organic EL device BL has a common structure for the regions G and B, so that the number of steps and time necessary for manufacturing the organic EL apparatus can be reduced.

In addition, the blue light emitting layers 5b in the organic EL devices WL1(b)L, and WL2 can be formed by common steps. In this way, the number of steps and time necessary for manufacturing the organic EL apparatus can be reduced.

FIG. 6(d) shows the structure of an organic EL apparatus based on a fifth mode (RoGo-Bb-Ww).

According to the organic EL apparatus based on the fifth mode, red light and green light can be obtained based on orange light from an organic EL device OL, blue light can be obtained from an organic EL device BL, and white light can be obtained from an organic EL device WL.

As shown in FIG. 6(d), the organic EL device OL is formed on a hole injection electrode 2 in the position corresponding to the regions R and G in FIG. 1(b). A red color filter layer CFR and a green color filter layer CFG are provided side by side under the organic EL device OL in the positions corresponding to the regions R and G in FIG. 1(b).

The organic EL device BL is formed on the hole injection electrode 2 in the position corresponding to the region B in FIG. 1(b). A blue color filter layer CFB is provided under the organic EL device BL. The organic EL device WL is formed on the hole injection electrode 2 in the position corresponding to the region W in FIG. 1(b).

In the organic EL apparatus in FIG. 6(d), orange light from the organic EL device OL is transmitted through the red color filter layer CFR and the green color filter layer CFG, so that red light and green light can be obtained.

Blue light from the organic EL device BL is transmitted through the blue color filter layer CFB, so that blue light can be obtained. White light can be obtained from the organic EL device WL.

The orange light from the organic EL device OL has higher emission intensity in the wavelength range of red light and green light than the white light from the organic EL device WL. The blue light from the organic EL device BL has higher emission intensity than the white light from the organic EL device WL in the wavelength range of blue light.

Therefore, red light having high emission intensity can be obtained by the red color filter layer CFR. Blue light having high emission intensity can be obtained by the blue color filter layer CFB. In this way, the luminous efficiency of the organic EL apparatus improves and the power consumption can be further reduced.

Since the organic EL device OL has a common structure for the regions R and G, the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be reduced.

FIG. 6(e) shows the structure of an organic EL apparatus based on a sixth mode (Ro-GbBb-Ww).

According to the organic EL apparatus based on the sixth mode, red light can be obtained based on orange light from an organic EL device OL, green light and blue light can be obtained based on blue light from an organic EL device BL, and white light can be obtained from an organic EL device WL.

As shown in FIG. 6(e), the organic EL device OL is formed on a hole injection electrode 2 in the position corresponding to the region R in FIG. 1(b). A red color filter layer CFR is provided under the organic EL device OL in the position corresponding to the region R.

The organic EL device BL is formed on the hole injection electrode 2 in the position corresponding to the regions G and B in FIG. 1(b). A green color filter layer CFG and a blue color filter layer CFB are provided side by side under the organic EL device BL in the position corresponding to the regions G and B in FIG. 1(b). The organic EL device WL is formed on the hole injection electrode 2 in the position corresponding to the region W in FIG. 1(b).

In the organic EL apparatus as shown in FIG. 6(e), orange light from the organic EL device OL passes through the red color filter layer CFR, so that red light can be obtained. Blue light from the organic EL device BL is transmitted through the green color filter layer CFG and the blue color filter layer CFB, so that green light and blue light can be obtained. White light can be obtained from the organic EL device WL.

The orange light from the organic EL device OL has higher emission intensity in the wavelength ranges of red light and green light than the white light from the organic EL device WL. The blue light from the organic EL device BL has higher emission intensity in the wavelength ranges of blue light than the white light from the organic EL device WL.

Therefore, red light having high emission intensity can be obtained by the red color filter layer CFR. Blue light having high emission intensity can be obtained by the blue color filter layer CFB. In this way, the luminous efficiency of the organic EL apparatus improves and the power consumption can be further reduced.

Since the organic EL device BL has a common structure for the regions G and B, the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be reduced.

FIG. 6(f) shows the structure of an organic EL apparatus based on a seventh mode (Ro-Gw-Bb-Ww).

According to the organic EL apparatus based on the seventh mode, red light can be obtained based on orange light from an organic EL device OL, green light can be obtained based on white light from a first organic EL device WL1, blue light can be obtained from an organic EL device BL, and white light can be obtained from a second organic EL device WL2.

As shown in FIG. 6(f), the organic EL device OL is formed on a hole injection electrode 2 in the position corresponding to the region R in FIG. 1(b). A red color filter layer CFR is provided under the organic EL device OL.

The first organic EL device WL1 is formed on the hole injection electrode 2 in the position corresponding to the region G in FIG. 1(b). A green color filter layer CFG is provided under the first organic EL device WL1.

The organic EL device BL is formed on the hole injection electrode 2 in the position corresponding to the region B in FIG. 1(b). A blue color filter layer CFB is provided under the organic EL device BL.

The second organic EL device WL2 is formed on the hole injection electrode 2 in the position corresponding to the region W in FIG. 1(b).

In the organic EL apparatus shown in FIG. 6(f), orange light from the organic EL device OL is transmitted through the red color filter layer CFR, so that red color can be obtained. Light from the first organic EL device WL1 is transmitted through the green color filter layer CFG, so that green light can be obtained. Blue light from the organic EL device BL is transmitted through the blue color filter layer CFB, so that blue light can be obtained. White light can be obtained from the second organic EL device WL2.

The orange light from the organic EL device OL has higher emission intensity in the wavelength range of red light than the white light from the organic EL devices WL1 and WL2. The blue light from the organic EL device BL has higher emission intensity in the wavelength range of blue light than the white light from the organic EL devices WL1 and WL2.

In this way, red light having high emission intensity can be obtained by the red color filter layer CFR. Blue light having high emission intensity can be obtained by the blue color filter layer CFB. In this way, the luminous efficiency of the organic EL apparatus improves and the power consumption can be further reduced.

Orange light emitting layers 5a in the organic EL devices OL and WL1, and blue light emitting layers 5b in the organic EL devices BL and WL2 can be formed by common steps. In this way, the number of steps and time necessary for manufacturing the organic EL apparatus can be reduced.

In the examples shown in FIGS. 5(a) to 5(c) and 6(d) to 6(f), red light, green light, and blue light can be obtained through the red color filter layer CFR, the green color filter layer CFG, and the blue color filter layer CFB, respectively, and therefore red light, green light, and blue light having high color purity can be obtained.

### Second Embodiment

Regarding an organic EL apparatus according to a second embodiment of the invention, combinations of a plurality of organic EL devices will be referred to as modes. First to seventh modes in the following description are the same as the first to seventh modes according to the first embodiment described above.

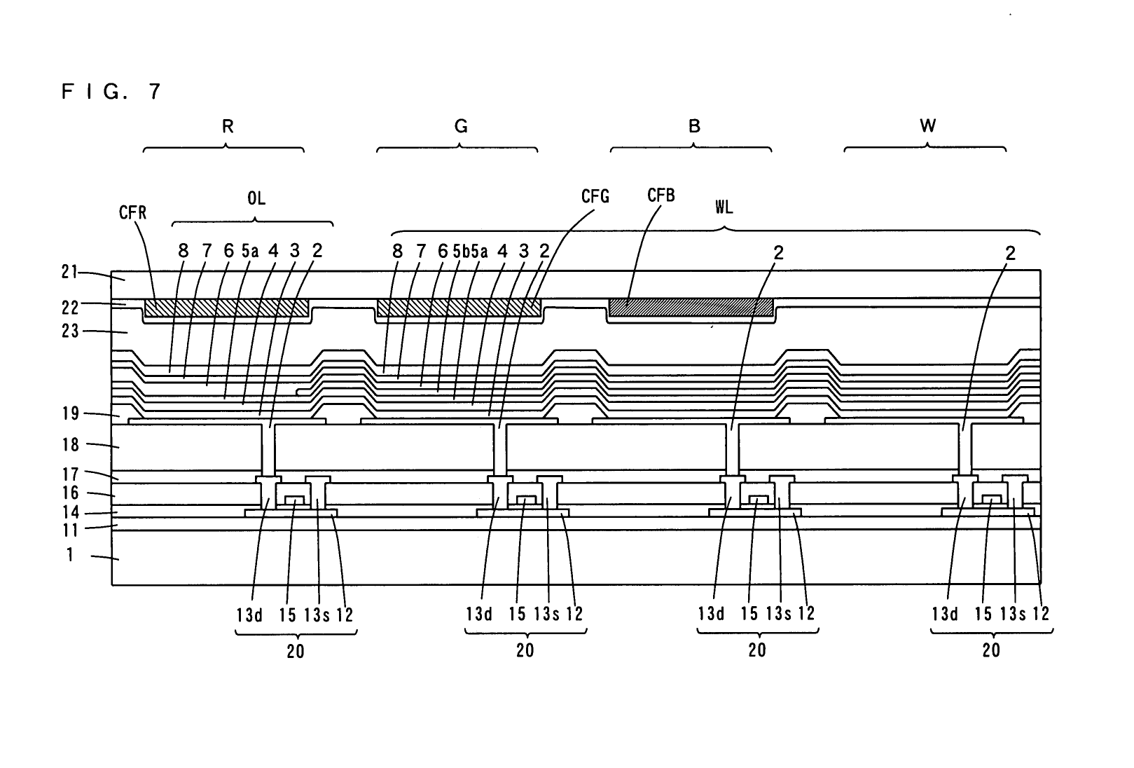

FIG. 7 is a sectional view of an example of the structure of an organic EL apparatus according to the second embodiment. The organic EL apparatus shown in FIG. 7 is different from the organic EL apparatus shown in FIG. 2 in the following points.

In the organic EL apparatus shown in FIG. 7, similarly to the organic EL apparatus in FIG. 2, a layered film 11, TFTs 20, a first interlayer insulating film 16, a second interlayer insulating film 17, a first planarization layer 18, a second planarization layer 19, and an organic EL device are formed on a substrate 1.

A green color filter layer CFG and a blue color filter layer CFB are provided side by side above an organic EL device WL in the position corresponding to the regions G and B in FIG. 1(b). A red color filter layer CFR is provided on an organic EL device OL in the position corresponding to the region R in FIG. 1(b).

A layered body including an overcoat layer 22, the red color filter layer CFR, the green color filter layer CFG, the blue color filter layer CFB, and a transparent seal substrate 21 provided on each other in this order is adhered on the organic EL device OL and the organic EL device WL through a transparent adhesive layer 23. In this way, an organic EL apparatus having a top emission structure is completed.

In the region R, orange light from the organic EL device OL is externally output through the red color filter layer CFR and the seal substrate 21. In the region G, white light from the organic EL device WL is externally output through the green color filter layer CFG and the seal substrate 21. In the region B, white light from the organic EL device WL is externally output through the blue color filter layer CFB and the seal substrate 21. In the region W, white light from the organic EL device WL is externally output only through the seal substrate 21.

In the organic EL apparatus shown in FIG. 7, the substrate 1 may be made of an opaque material. The hole injection electrode 2 is made of a layered structure including an indium-tin-oxide (ITO) film about as thick as 50 nm, and an aluminum, chromium or silver film about as thick as 100 nm. In this case, the hole injection electrode 2 reflects light generated by the organic EL devices OL and WL toward the seal substrate 21.

The electron injection electrode 7 is made of a transparent material. The electron injection electrode 7 is for example made of a layered structure including an indium-tin-oxide (ITO) film about as thick as 100 nm and a silver film about as thick as 20 nm.

The overcoat layer 22 is for example made of acrylic resin about as thick as 1 μm. As the seal substrate 21, for example a layer made of glass and silicon oxide (SiO₂) or silicon nitride (SiNₓ) may be used.

The organic EL apparatus in FIG. 7 having the top emission structure allows the region on the TFT 20 to be used as a pixel area. More specifically, in the organic EL apparatus in FIG. 7, a color filter layer larger than each of the color filter layers in FIG. 2 can be used. In this way, a wider area can be secured for the pixel region, and therefore the luminance of the organic EL apparatus improves.

Since the organic EL device WL has a common structure for the regions G, B, and W, the number of steps and time necessary for manufacturing the organic EL apparatus can be reduced.

Orange light emitting layers 5a in the organic EL devices WL and OL can be formed by common steps. In this way, the number of steps and time necessary for manufacturing the organic EL apparatus can be further reduced.

Note that according to the embodiment, the organic EL apparatus in FIG. 7 is produced based on the first mode (Rr-GwBwWw).

Now, another example of the organic EL apparatus having the top emission structure in FIG. 7 will be described.

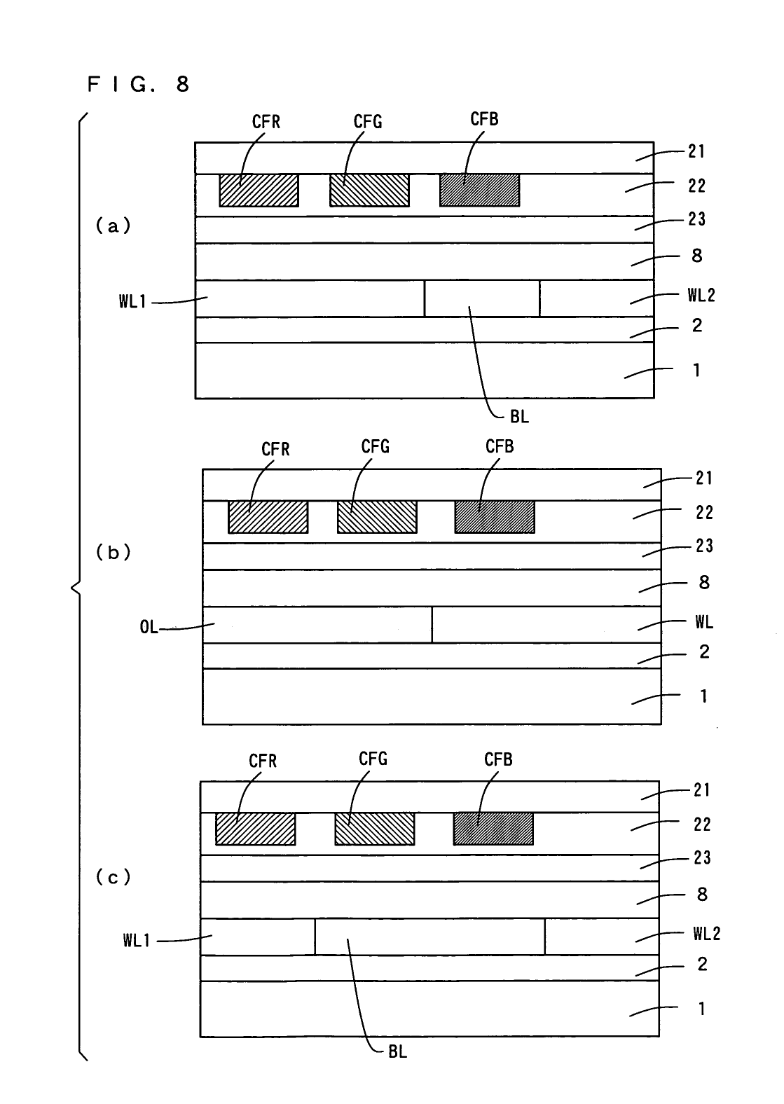

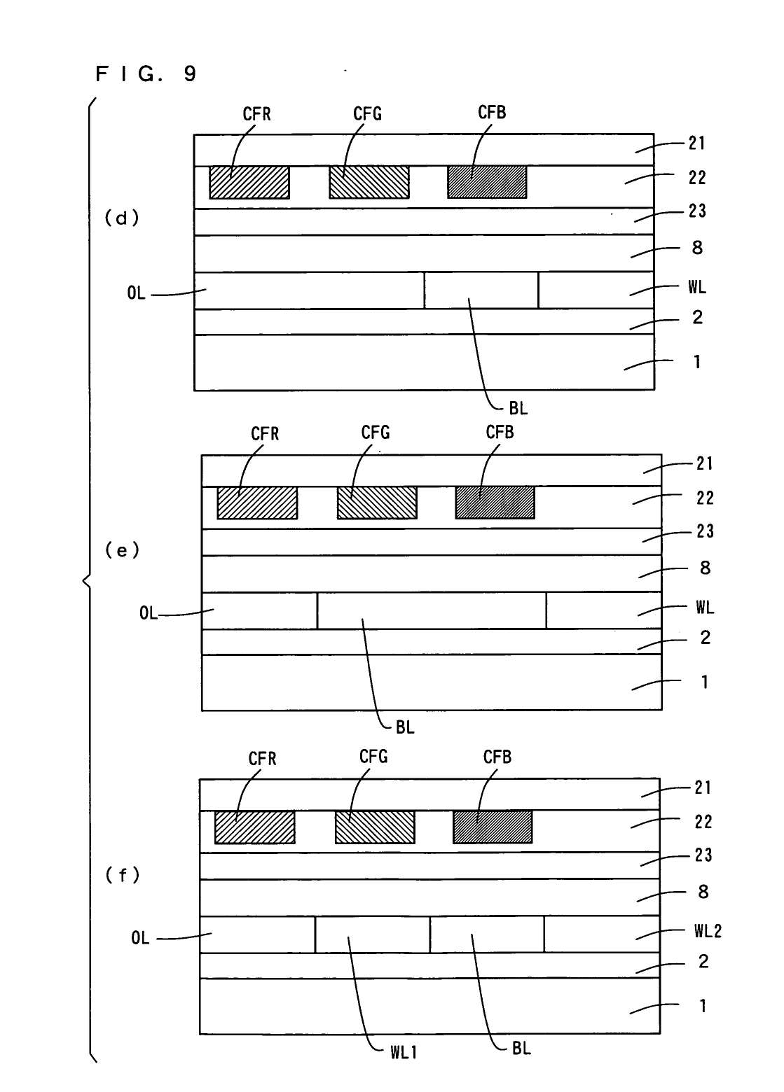

FIGS. 8(a) to 8(c) and 9(d) to 9(f) show the structures of organic EL apparatuses based on a plurality of modes according to the second embodiment. Note that in FIGS. 8(a) to 8(c) and 9(d) to 9(f), the parts already described in connection with FIGS. 5(a) to 5(c) and 6(d) to 6(f) will not omitted from the description.

FIG. 8(a) is a view showing the structure of the organic EL apparatus based on the second mode (RwGw-Bb-Ww).

As shown in FIG. 8(a), a red color filter layer CFR and a green color filter layer CFG are provided side by side above a first organic EL device WL1 in the positions corresponding to the regions R and G in FIG. 1(b). A blue color filter layer CFB is provided above an organic EL device BL in the position corresponding to the region B in FIG. 1(b).

In the organic EL apparatus shown in FIG. 8(a), white light from the first organic EL device WL1 is transmitted through the red color filter layer CFR and the green color filter layer CFG, so that red light and green light can be obtained. Blue light from the organic EL device BL passes through the blue color filter layer CFB, so that blue light can be obtained. White light can be obtained from a second organic EL device WL2.

In this way, blue light having high emission intensity can be obtained by the blue color filter layer CFB. Therefore, the luminous efficiency of the organic EL apparatus improves and the power consumption can be reduced.

Since the organic EL device WL1 has a common structure for the regions R and G, the number of steps and time necessary for the organic EL apparatus can be reduced.

Blue light emitting layers 5b in the organic EL devices WL1(b)L, and WL2 can be formed by common steps. In this way, the number of steps and time for manufacturing the organic EL apparatus can be reduced.

FIG. 8(b) is a view showing the structure of an organic EL apparatus based on the third mode (RoGo-BwWw).

As shown in FIG. 8(b), a red color filter layer CFR and a green color filter layer CFG are provided side by side above the organic EL device OL in the positions corresponding to the regions R and G in FIG. 1(b). A blue color filter layer CFB is provided above the organic EL device WL in the position corresponding to the region B in FIG. 1(b).

In the organic EL apparatus in FIG. 8(b), orange light from the organic EL device OL is transmitted through the red color filter layer CFR and the green color filter layer CFG, so that red light and green light can be obtained. White light from the organic EL device WL is transmitted through the blue color filter layer CFB, so that blue light can be obtained, and while white light can be obtained from the organic EL device WL.

In this way, red light having high emission intensity can be obtained by the red color filter layer CFR. Therefore, the luminous efficiency of the organic EL apparatus improves and the power consumption can be reduced.

The organic EL device OL has a common structure for the regions R and G, and the organic EL device WL has a common structure for the regions B and W. Therefore, the number of steps and time for manufacturing the organic EL apparatus can be reduced.

Orange light emitting layers 5a in the organic EL devices OL and WL can be formed by common steps. In this way, the number of steps and time for manufacturing the organic EL apparatus can be reduced.

FIG. 8(c) is a view showing the structure of an organic EL apparatus based on the fourth mode (Rw-GbBb-Ww).

As shown in FIG. 8(c), a red color filter layer CFR is provided above a first organic EL device WL1 in the position corresponding to the region R in FIG. 1(b). A green color filter layer CFG and a blue color filter layer CFB are provided side by side above an organic EL device BL in the positions corresponding to the regions G and B in FIG. 1(b).

In the organic EL apparatus in FIG. 8(c), white light from the first organic EL device WL1 is transmitted through the red color filter layer CFR, so that red light can be obtained. Blue light from the organic EL device BL is transmitted through the green color filter layer CFG and the blue color filter layer CFB, so that green light and blue light can be obtained. White light can be obtained from a second organic EL device WL2.

In this way, blue light having high emission intensity can be obtained by the blue color filter layer CFB. Therefore, the luminous efficiency of the organic EL apparatus improves and the power consumption can be reduced.

Furthermore, the organic EL device BL has a common structure for the regions G and B, and therefore the number of steps and time necessary for manufacturing the organic EL apparatus can be reduced.

Blue light emitting layers 5b in the organic EL devices WL1(b)L and WL2 can be formed by common steps. Therefore, the number of steps and time necessary for manufacturing the organic EL apparatus can be reduced.

FIG. 9(d) is a view showing the structure of an organic EL apparatus based on the fifth mode (RoGo-Bb-Ww).

As shown in FIG. 9(d), a red color filter layer CFR and a green color filter layer CFG are provided side by side above an organic EL device OL in the positions corresponding to the regions R and G in FIG. 1(b). A blue color filter layer CFB is provided above an organic EL device BL in the position corresponding to the region B in FIG. 1(b).

In the organic EL apparatus shown in FIG. 9(d), orange light from the organic EL device OL passes through the red color filter layer CFR and the green color filter layer CFG, so that red light and green light can be obtained. Blue light from the organic EL device BL passes through the blue color filter layer CFB, so that blue light can be obtained. White light can be obtained by the organic EL device WL.

In this way, red light having high emission intensity can be obtained by the red color filter layer CFR. Blue light having high emission intensity can be obtained by the blue color filter layer CFB. In this way, the luminous efficiency of the organic EL apparatus improves and the power consumption can be reduced.

Since the organic EL device OL has a common structure for the regions R and G, the number of steps and time necessary for manufacturing the organic EL apparatus can be reduced.

In addition, blue light emitting layers 5b in the organic EL devices BL and WL can be formed by common steps. In this way, the number of steps and time necessary for manufacturing the organic EL apparatus can be reduced.

FIG. 9(e) is a view showing the structure of an organic EL apparatus based on the sixth mode (Ro-GbBb-Ww).

As shown in FIG. 9(e), a red color filter layer CFR is provided above an organic EL device OL in the position corresponding to the region R in FIG. 1(b). A green color filter layer CFG and a blue color filter layer CFB are provided side by side above an organic EL device BL in the positions corresponding to the regions G and B in FIG. 1(b).

In the organic EL apparatus in FIG. 9(e), orange light from the organic EL device OL is passed through the red color filter layer CFR, so that red light can be obtained. Blue light from the organic EL device BL is transmitted through the green color filter layer CFG and the blue color filter layer CFB, so that green light and blue light can be obtained. White light can be obtained from an organic EL device WL.

In this way, red light having high emission intensity can be obtained by the red color filter layer CFR. Blue light having high emission intensity can be obtained by the blue color filter layer CFB. Therefore, the luminous efficiency of the organic EL apparatus improves and the power consumption can be reduced.

Since the organic EL device BL has a common structure for the regions G and B, the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be reduced.

FIG. 9(f) is a view showing the structure of an organic EL apparatus based on the seventh mode (Ro-Gw-Bb-Ww).

As shown in FIG. 9(f), a red color filter layer CFR is provided above an organic EL device OL in the position corresponding to the region R in FIG. 1(b). A green color filter layer CFG is provided above a first organic EL device WL1 in the position corresponding to the region G in FIG. 1(b). A blue color filter layer CFB is provided above the organic EL device BL in the position corresponding to the region B in FIG. 1(b).

In the organic EL apparatus in FIG. 9(f), orange light from the organic EL device OL is passed through the red color filter layer CFR, so that red light can be obtained. Light from a first organic EL device WL1 is transmitted through the green color filter layer CFG, so that green light can be obtained. Blue light from the organic EL device BL is passed through the blue color filter layer CFB, so that blue light can be obtained. White light can be obtained from a second organic EL device WL2.

In this way, red light having high emission intensity can be obtained by the red color filter layer CFR. Blue light having high emission intensity can be obtained by the blue color filter layer CFB. Therefore, the luminous efficiency of the organic EL apparatus improves and the power consumption can be further reduced.

Orange light emitting layers 5a in the organic EL devices OL and WL1, and blue light emitting layers 5b in the organic EL devices BL and WL2 can be formed by common steps. In this way, the number of steps and time necessary for manufacturing the organic EL apparatus can be reduced.

In the examples in FIGS. 8(a) to 8(c) and 9(d) to 9(f), red light, green light, and blue light obtained through the red color filter layer CFR, the green color filter layer CFG, and the blue color filter layer CFB can have high purity.

### Third Embodiment

The structure of an organic EL apparatus according to a third embodiment of the invention is different from that of the organic EL apparatus in FIG. 2 in that an organic EL device WL is not formed in the position corresponding to the region W in FIG. 1(b).

In the organic EL apparatus according to the embodiment, combinations of a plurality of organic EL devices will also be referred to as modes.

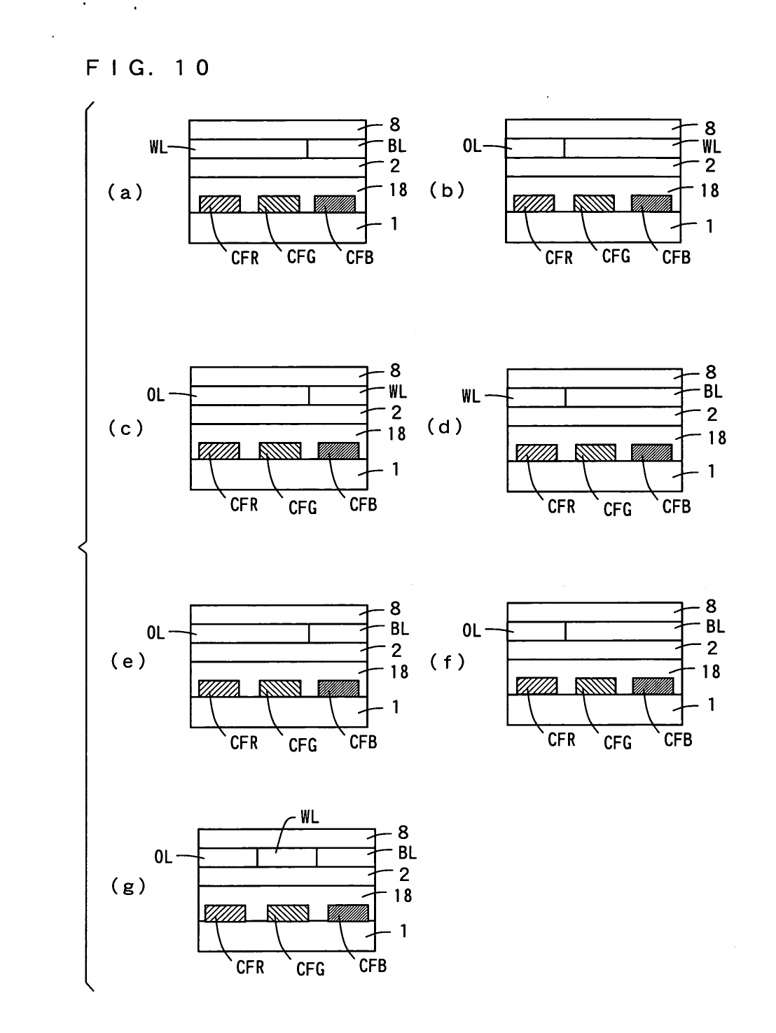

FIGS. 10(a) to 10(f) are views showing the structures of organic EL apparatuses based on a plurality of modes according to the third embodiment.

FIG. 10(a) is a view showing the structure of an organic EL apparatus based on an eighth mode (RwGw-Bb).

According to the organic EL apparatus based on the eighth mode, red light and green light can be obtained based on white light from an organic EL device WL, and blue light can be obtained from an organic EL device BL that emits blue light.

As shown in FIG. 10(a), the organic EL device WL is formed on a hole injection electrode 2 in the position corresponding to the regions R and G in FIG. 1(b). A red color filter layer CFR and a green color filter layer CFG are provided side by side under the organic EL device WL in the positions corresponding to the regions R and G in FIG. 1(b).

The organic EL device BL is formed on the hole injection electrode 2 in the position corresponding to the region B in FIG. 1(b). A blue color filter layer CFB is provided under the organic EL device BL.

In the organic EL apparatus in FIG. 10(a), white light from the organic EL device WL is transmitted through the red color filter layer CFR and the green color filter layer CFG, so that red light and green light can be obtained. Blue light from the organic EL device BL is transmitted through the blue color filter layer CFB, so that blue light can be obtained.

In this way, blue light having high emission intensity can be obtained by the blue color filter layer CFB. Therefore, the luminous efficiency of the organic EL apparatus improves and the power consumption can be reduced.

Since the organic EL device WL has a common structure for the regions R and G, the number of steps and time necessary for manufacturing the organic EL apparatus can be reduced.

Blue light emitting layers 5b in the organic EL devices WL and BL can be formed by common steps. In this way, the number of steps and time necessary for manufacturing the organic EL apparatus can be further reduced.

FIG. 10(b) is a view showing the structure of an organic EL apparatus based on a ninth mode (Ro-GwBw).

In the organic EL apparatus based on the ninth mode, red light can be obtained from an organic EL device OL, and green light and blue light can be obtained from an organic EL device WL.

As shown in FIG. 10(b), the organic EL device OL is provided on a hole injection electrode 2 in the position corresponding to the region R in FIG. 1(b). A red color filter layer CFR is provided under the organic EL device OL.

An organic EL device WL is formed on the hole injection electrode 2 in the position corresponding to the regions G and B in FIG. 1(b). A green color filter layer CFG and a blue color filter layer CFB are provided side by side under the organic EL device WL in the positions corresponding to the regions G and B in FIG. 1(b).

In the organic EL apparatus shown in FIG. 10(b), orange light from the organic EL device OL is passed through the red color filter layer CFR, so that red light can be obtained. White light from the organic EL device WL is transmitted through the green color filter layer CFG and the blue color filter layer CFB, so that green light and blue light can be obtained.

In this way, red light having high emission intensity can be obtained by the red color filter layer CFR. Therefore, the luminous efficiency of the organic EL apparatus improves and the power consumption can be reduced.

Since the organic EL device WL has a common structure for the regions G and B, the number of steps and time necessary for manufacturing the organic EL apparatus can be reduced.

Orange light emitting layers 5a in the organic EL devices OL and WL can be formed by common steps. In this way, the number of steps and time necessary for manufacturing the organic EL apparatus can be reduced.

FIG. 10(c) is a view showing the structure of an organic EL apparatus based on a tenth mode (RoGo-Bw).

In the organic EL apparatus based on the tenth mode, red light and green light can be obtained from an organic EL device OL, and blue light can be obtained from an organic EL device WL.

As shown in FIG. 10(c), the organic EL device OL is formed on a hole injection electrode 2 in the position corresponding to the regions R and G in FIG. 1(b). A red color filter layer CFR and a green color filter layer CFG are provided side by side under the organic EL device OL in the positions corresponding to the regions R and G in FIG. 1(b).

The organic EL device WL is formed on the hole injection electrode 2 in the position corresponding to the region B in FIG. 1(b). The blue color filter layer CFB is provided under the organic EL device WL.

In the organic EL apparatus in FIG. 10(c), orange light from the organic EL device OL is transmitted through the red color filter layer CFR and the green color filter layer CFG, so that red light and green light can be obtained. White light from the organic EL device WL is transmitted through the blue color filter layer CFB and blue light can be obtained.

In this way, red light having high emission intensity can be obtained by the red color filter layer CFR. Therefore, the luminous efficiency of the organic EL apparatus improves and the power consumption can be reduced.

The organic EL device OL has a common structure for the regions R and G, and therefore the number of steps and time necessary for manufacturing the organic EL apparatus can be reduced.

Orange light emitting layers 5a in the organic EL devices OL and WL can be formed by common steps. Therefore, the number of steps and time necessary for manufacturing the organic EL apparatus can be further reduced.

FIG. 10(d) is a view showing the structure of an organic EL apparatus based on an eleventh mode (Rw-GbBb).

In the organic EL apparatus based on the eleventh mode, red light can be obtained from an organic EL device WL, and green light and blue light can be obtained from an organic EL device BL.

As shown in FIG. 10(d), the organic EL device WL is formed on a hole injection electrode 2 in the position corresponding to the region R in FIG. 1(b). A red color filter layer CFR is provided under the organic EL device WL.

The organic EL device BL is formed on the hole injection electrode 2 in the position corresponding to the regions G and B in FIG. 1(b). A green color filter layer CFG and a blue color filter layer CFB are provided side by side under the organic EL device BL in the positions corresponding to the regions G and B in FIG. 1(b).

In the organic EL apparatus in FIG. 10(d), white light from the organic EL device WL is transmitted through the red color filter layer CFR, so that red light can be obtained. Light from the organic EL device BL is transmitted through the green color filter layer CFG and the blue color filter layer CFB, so that green light and blue light can be obtained.

In this way, blue light having high emission intensity can be obtained by the blue color filter layer CFB. Therefore, the luminous efficiency of the organic EL apparatus improves and the power consumption can be reduced.

Since the organic EL device BL has a common structure for the regions G and B, the number of steps and time necessary for manufacturing the organic EL apparatus can be reduced.

Blue light emitting layers 5b in the organic EL devices WL and BL can be formed by common steps. In this way, the number of steps and time necessary for manufacturing the organic EL apparatus can be reduced.

FIG. 10(e) is a view showing the structure of an organic EL apparatus based on a twelfth mode (RoGo-Bb).

In the organic EL apparatus based on the twelfth mode, red light and green light can be obtained from an organic EL device OL, and blue light can be obtained from an organic EL device BL.

As shown in FIG. 10(e), the organic EL device OL is formed on a hole injection electrode 2 in the position corresponding to the regions R and G in FIG. 1(b). A red color filter layer CFR and a green color filter layer CFG are provided side by side under the organic EL device OL in the positions corresponding to the regions R and G in FIG. 1(b).

The organic EL device BL is formed on the hole injection electrode 2 in the position corresponding to the region B in FIG. 1(b). A blue color filter layer CFB is provided under the organic EL device BL.

In the organic EL apparatus in FIG. 10(e), red light from the organic EL device OL is transmitted through the red color filter layer CFR and the green color filter layer CFG, so that red light and green light can be obtained. Blue light from the organic EL device BL is transmitted through the blue color filter layer CFB, so that blue light can be obtained.

In this way, red light having high emission intensity can be obtained by the red color filter layer CFR. Blue light having high emission intensity can be obtained by the blue color filter layer CFB. Therefore, the luminous efficiency of the organic EL apparatus improves and the power consumption can be reduced.

Since the organic EL device OL has a common structure for the regions R and G, the number of steps and time necessary for manufacturing the organic EL apparatus can be reduced.

FIG. 10(f) is a view showing the structure of an organic EL apparatus based on a thirteenth mode (Ro-GbBb).

In the organic EL apparatus based on the thirteenth mode, red light can be obtained from an organic EL device OL, and green light and blue light can be obtained from an organic EL device BL.

As shown in FIG. 10(f), the organic EL device OL is formed on a hole injection electrode 2 in the position corresponding to the region R in FIG. 1(b). A red color filter layer CFR is provided under the organic EL device OL.

The organic EL device BL is formed on the hole injection electrode 2 in the position corresponding to the regions G and B in FIG. 1(b). A green color filter layer CFG and a blue color filter layer CFB are provided under the organic EL device BL in the positions corresponding to the regions G and B in FIG. 1(b).

In the organic EL apparatus in FIG. 10(f), red light from the organic EL device OL is transmitted through the red color filter layer CFR, so that red light can be obtained. Light from the organic EL device BL is transmitted through the green color filter layer CFG and the blue color filter layer CFB, so that green light and blue light can be obtained.

In this way, red light having high emission intensity can be obtained by the red color filter layer CFR. Blue light having high emission intensity can be obtained by the blue color filter layer CFB. Therefore, the luminous efficiency of the organic EL apparatus improves and the power consumption can be further reduced.

Since the organic EL device BL has a common structure for the regions G and B, the number of steps and time necessary for manufacturing the organic EL apparatus can be reduced.

FIG. 10(g) is a view showing the structure of an organic EL apparatus based on a fourteenth mode (Ro-Gw-Bb).

In the organic EL apparatus based on the fourteenth mode, red light can be obtained from an organic EL device OL, green light can be obtained from an organic EL device WL, and blue light can be obtained from an organic EL device BL.

As shown in FIG. 10(g), the organic EL device OL is formed on a hole injection electrode 2 in the position corresponding to the region R in FIG. 1(b). A red color filter layer CFR is provided under the organic EL device OL.

The organic EL device WL is formed on the hole injection electrode 2 in the position corresponding to the region G in FIG. 1(b). A green color filter layer CFG is provided under the organic EL device WL.

The organic EL device BL is formed on the hole injection electrode 2 in the position corresponding to the region B in FIG. 1(b). A blue color filter layer CFB is provided under the organic EL device BL.

In the organic EL apparatus in FIG. 10(g), orange light from the organic EL device OL is passed through the red color filter layer CFR, so that red light can be obtained. White light from the organic EL device WL is transmitted through the green color filter layer CFG, so that green light can be obtained. Blue light from the organic EL device BL is passed through the blue color filter layer CFB, so that blue light can be obtained.

In this way, red light having high emission intensity can be obtained by the red color filter layer CFR. Blue light having high emission intensity can be obtained by the blue color filter layer CFB. Therefore, the luminous efficiency of the organic EL apparatus improves and the power consumption can be reduced.

Since an orange light emitting layer 5a in the organic EL device OL or a blue light emitting layer 5b in the organic EL device BL, and an orange light emitting layer 5a or a blue light emitting layer 5b in the organic EL device WL can be formed by common steps. In this way, the number of steps and time necessary for manufacturing the organic EL apparatus can be reduced.

Note that the apparatuses described in connection with FIGS. 10(a) to 10(g) are bottom emission type organic EL apparatuses, but the invention can equally be applied to a top emission type organic EL apparatus.

In the examples in FIGS. 10(a) to 10(g), red light, green light, and blue light can be obtained through the red color filter layer CFR, the green color filter layer CFG, and the blue color filter layer CFB, respectively and therefore have high purity.

### Effects of First to Third Embodiments

The organic EL apparatuses according to the above described embodiments each have one of the following arrangements: an arrangement that emits orange light from an organic EL device OL, an arrangement that emits blue light from an organic EL device BL, and an arrangement that emits orange light from an organic EL device OL and blue light from an organic EL device BL. In this way, the luminous efficiency for orange light or/and blue light improves. Therefore, the power consumption can be reduced.

### Fourth Embodiment

The arrangement of light emitting regions for one pixel in an organic EL apparatus according to a fourth embodiment of the invention is the same as that of the organic EL apparatus according to the first embodiment shown in FIGS. 1(a) and 1(b).

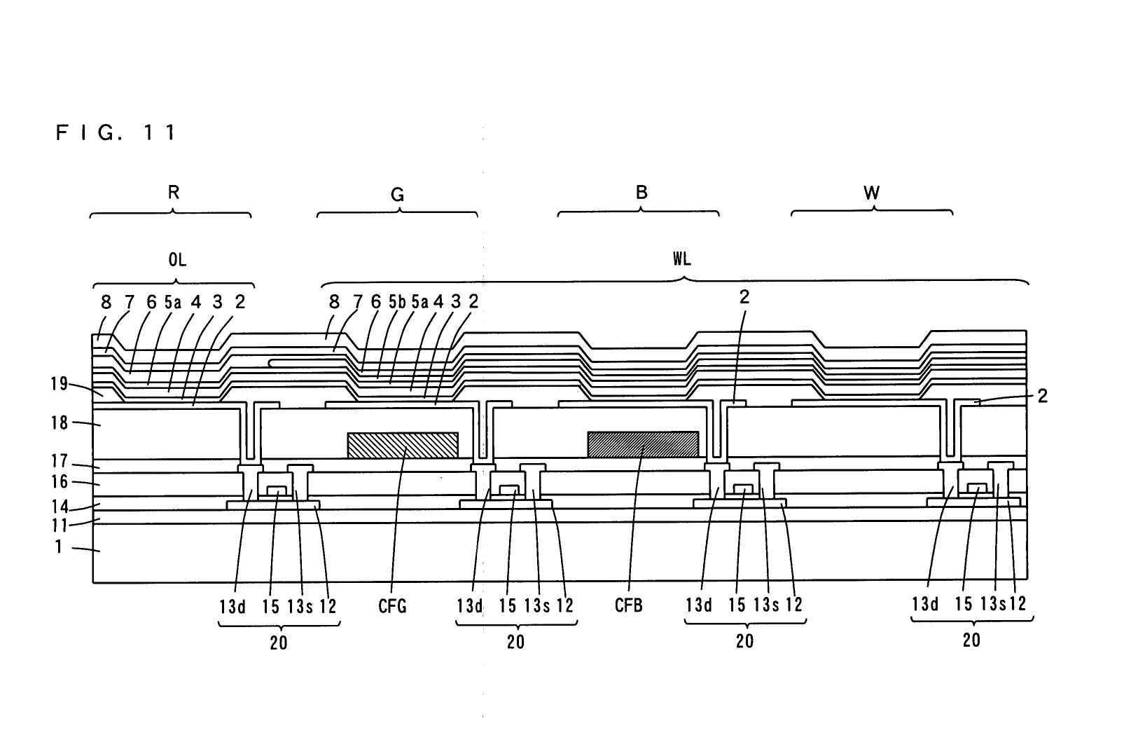

FIG. 11 is a sectional view of an example of the structure of the organic EL apparatus according to the embodiment. Note that the example of the organic EL apparatus shown in FIG. 11 and another example of the organic EL apparatus that will be described have sections corresponding to the top view in FIG. 1(b).

The structure of the organic EL apparatus according to the fourth embodiment is different from that of the organic EL apparatus according to the first embodiment in that a red color filter layer CFR is not provided under an organic EL device OL and on a second interlayer insulating film 17.

According to the embodiment, orange light generated by the organic EL device OL is used as red light among three primary colors. In this way, the luminous efficiency improves as compared to the case of changing white light from the organic EL device WL into red light using a red color filter layer. Therefore, the power consumption can be reduced.

Since the organic EL device WL has a common structure for the regions G, B, and W, the number of steps and time necessary for manufacturing the organic EL apparatus can be reduced.

In addition, since orange light emitting layers 5a in the organic EL device WL and OL can be formed by common steps. In this way, the number of steps and time necessary for manufacturing the organic EL apparatus can be more reduced.

Now, a plurality of other examples of the organic EL apparatus will be described.

To start with, the structures of other examples of an organic EL apparatus according to the embodiment are given in Table 1. Note that the modes in Table 1 are the same as those described in connection with the first embodiment, and combinations of a plurality of color filter layers in each mode will be referred to as patterns. The presence and absence of each of a red color filter layer CFR, a green color filter layer CFG, and a blue color filter layer CFB are indicated by “0” and “x” in Table 1.

TABLE 1

| | 2nd mode | 3rd mode | 4th mode | 5th mode | | | 6th mode | | | 7th mode | | |
|---|---|---|---|---|---|---|---|---|---|---|---|---|
| | (RwGw-Bb-Ww) | (RoGo-BwWw) | (Rw-GbBb-Ww) | (RoGo-Bb-Ww) | | | (Ro-GbBb-Ww) | | | (Ro-Gw-Bb-Ww) | | |
| pattern | — | — | — | 1 | 2 | 3 | 1 | 2 | 3 | 1 | 2 | 3 |
| CFR | ∘ | x | ∘ | x | x | ∘ | x | x | ∘ | x | x | ∘ |
| CFG | ∘ | ∘ | ∘ | ∘ | ∘ | ∘ | ∘ | ∘ | ∘ | ∘ | ∘ | ∘ |
| CFB | x | ∘ | x | ∘ | x | x | ∘ | x | x | x | ∘ | x |

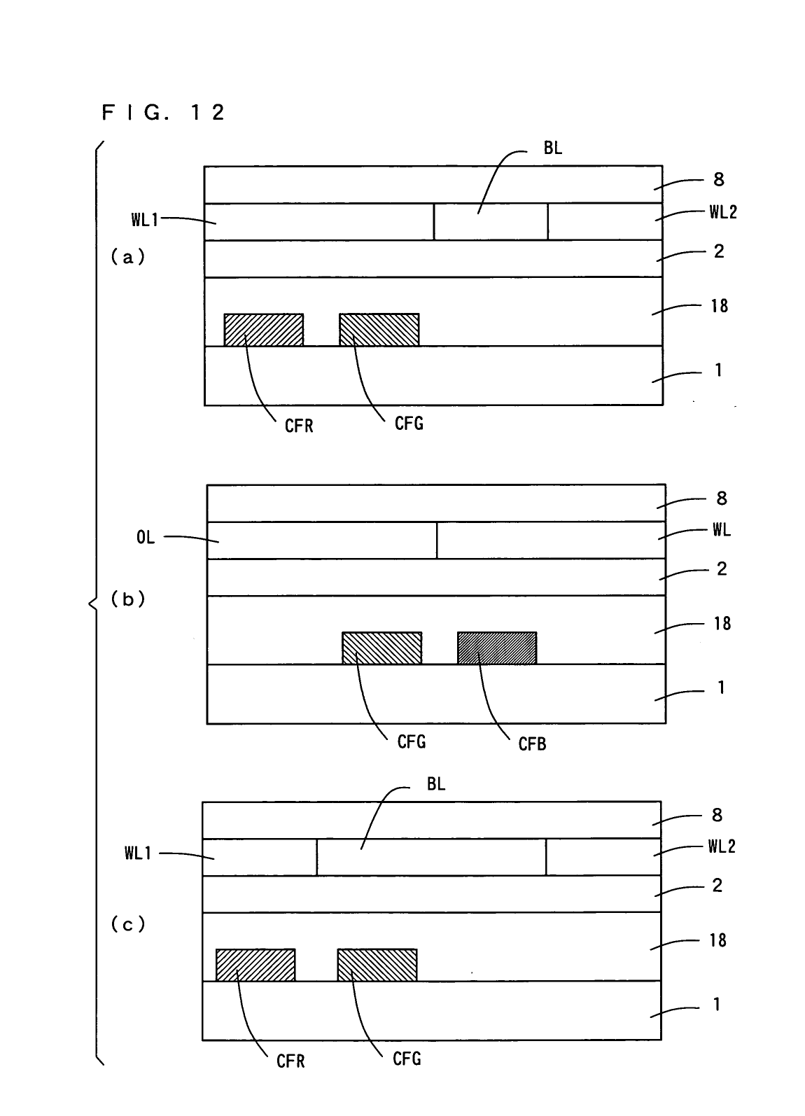

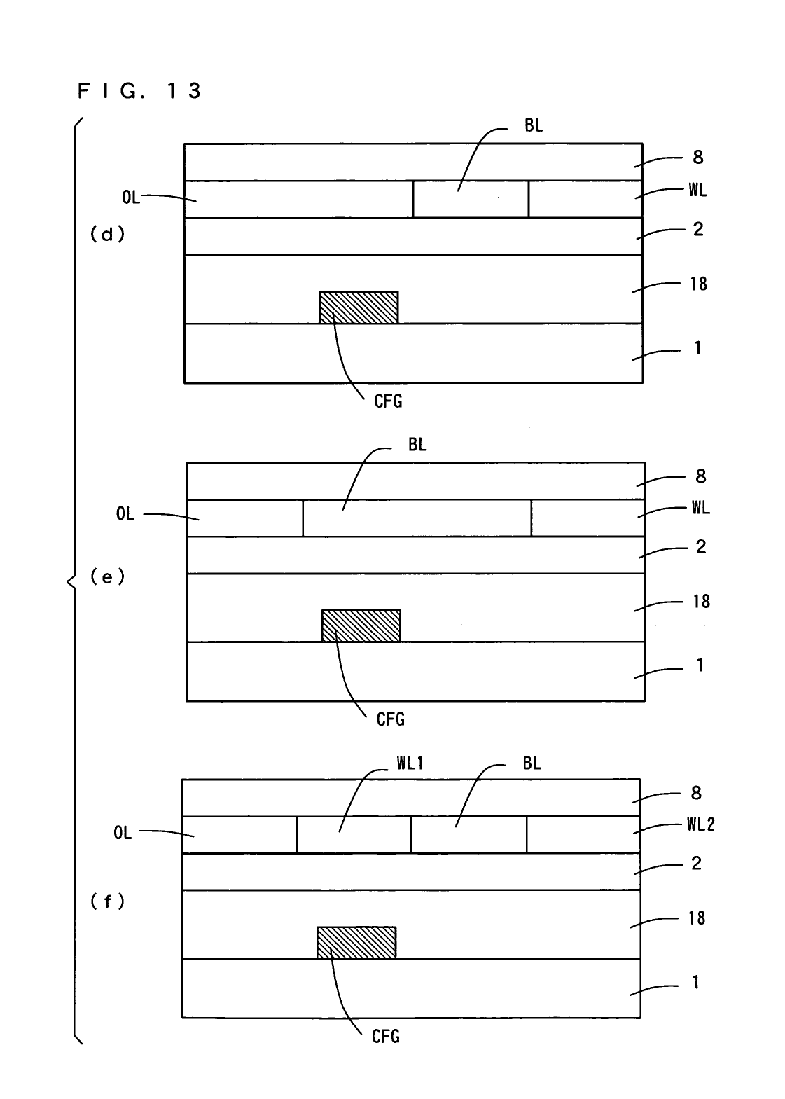

FIGS. 12(a) to 12(c) and 13(d) to 13(f) are views each showing the structure of an organic EL apparatus based on one of the modes in Table 1. Note that the structure of the organic EL apparatus according to the embodiment has been described in detail in connection with FIG. 11, and therefore the organic EL apparatus will briefly be described regarding each mode in connection with FIGS. 12(a) to 12(c) and 13(d) to 13(f).

FIG. 12(a) is a view showing the structure of an organic EL apparatus based on the first mode in Table 1.

The structure of the organic EL apparatus in FIG. 12(a) is different from that of the organic EL apparatus in FIG. 5(a) in that there is no blue color filter layer CFB provided.

In the organic EL apparatus shown in FIG. 12(a), white light from a first organic EL device WL1 is transmitted through a red color filter layer CFR and a green color filter layer CFG, so that red light and green light can be obtained. Blue light and white light can be obtained from an organic EL device BL and a second organic EL device WL2, respectively. In this way, the blue light is not attenuated, in other words, the luminous efficiency for the blue light improves.

The organic EL device WL1 has a common structure for the regions R and G, and therefore the number of steps and time necessary for manufacturing the organic EL apparatus can be reduced.

Blue light emitting layers 5b in the organic EL devices WL1(b)L, and WL2 can be formed by common steps. In this way, the number of steps and time necessary for manufacturing the organic EL apparatus can be more reduced.

FIG. 12(b) is a view showing the structure of an organic EL apparatus based on the third mode in Table 1.

The structure of the organic EL apparatus in FIG. 12(b) is different from that of the organic EL apparatus according to the first embodiment in FIG. 5(b) in that there is no red color filter layer CFR provided.

In the organic EL apparatus shown in FIG. 12(b), red light can be obtained from an organic EL device OL and white light from the organic EL device OL is transmitted through a green color filter layer CFG, so that green light can be obtained. White light from an organic EL device WL is transmitted through a blue color filter layer CFB, so that blue light can be obtained and white light can be obtained from the organic EL device WL. In this way, since the red color is not attenuated, the luminous efficiency for the red light improves.

The organic EL device OL has a common structure for the regions R and G, and the organic EL device WL has a common structure for the regions B and W. Therefore, the number of steps and time necessary for manufacturing the organic EL apparatus can be reduced.

Orange light emitting layers 5a in the organic EL devices OL and WL can be formed by common steps. In this way, the number of steps and time necessary for manufacturing the organic EL apparatus can be more reduced.

FIG. 12(c) is a view showing the structure of an organic EL apparatus based on the fourth mode in Table 1.

The structure of the organic EL apparatus in FIG. 12(c) is different from that of the organic EL apparatus in FIG. 5(c) in that there is no blue color filter layer CFB provided.

In the organic EL apparatus shown in FIG. 12(c), white light from a first organic EL device WL1 is transmitted through a red color filter layer CFR, so that red light can be obtained. Blue light from an organic EL device BL is transmitted through a green color filter layer CFG, so that green light can be obtained and blue light can be obtained from the organic EL device BL. White light can be obtained from a second organic EL device WL2. In this way, the luminous efficiency for blue light improves because the blue light is not attenuated.

The organic EL device BL has a common structure for the regions G and B, and therefore the number of steps and time necessary for manufacturing the organic EL apparatus can be reduced.

Blue light emitting layers 5b in the organic EL devices WL1(b)L, and WL2 can be formed by common steps. In this way, the number of steps and time necessary for manufacturing the organic EL apparatus can be more reduced.

With reference to FIGS. 13(d) to 13(f), pattern 1 in each of the fifth to seventh modes in Table 1 will be described by way of illustration.

FIG. 13(d) is a view showing the structure of an organic EL apparatus based on the fifth mode in Table 1.

The structure of the organic EL apparatus in FIG. 13(d) is different from that of the organic EL apparatus in FIG. 6(d) in that neither a red color filter layer CFR nor a blue color filter layer CFB is provided.

In the organic EL apparatus shown in FIG. 13(d), red light can be obtained from an organic EL device OL. Orange light from the organic EL device OL is transmitted through a green color filter layer CFG, so that green light can be obtained. Blue light and white light can be obtained from an organic EL device BL and an organic EL device WL, respectively. In this way, the luminous efficiency for red light and blue light improves because the red light and blue light are not attenuated.

The organic EL device OL has a common structure for the regions R and G, and therefore the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be further reduced.

FIG. 13(e) is a view showing the structure of an organic EL apparatus based on the sixth mode in Table 1.

The structure of the organic EL apparatus in FIG. 13(e) is different from that of the organic EL apparatus according to the first embodiment in FIG. 6(e) in that neither a red color filter layer CFR nor a blue color filter layer CFB is provided.

In the organic EL apparatus shown in FIG. 13(e), red light can be obtained from an organic EL device OL. Blue light from an organic EL device BL is transmitted through a green color filter layer CFG, so that green light can be obtained. Blue light can be obtained from an organic EL device BL. White light can be obtained from an organic EL device WL. In this way, the luminous efficiency for red light and blue light improves because the red light and blue light are not attenuated.

The organic EL device BL has a common structure for the regions G and B, and therefore the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be more reduced.

FIG. 13(f) is a view showing the structure of an organic EL apparatus based on the seventh mode in Table 1.

The structure of the organic EL apparatus in FIG. 13(f) is different from that of the organic EL apparatus in FIG. 6(f) in that neither a red color filter layer CFR nor a blue color filter layer CFB is provided.

In the organic EL apparatus shown in FIG. 13(f), red light can be obtained from an organic EL device OL. White light from an organic EL device WL1 is transmitted through a green color filter layer CFG, so that green light can be obtained. Blue light can be obtained from an organic EL device BL. White light can be obtained from a second organic EL device WL2. In this way, the luminous efficiency for red light and blue light improves because the red light and blue light are not attenuated.

Orange light emitting layers 5a in the organic EL devices OL and WL1, and blue light emitting layers 5b in the organic EL devices BL and WL2 can be formed by common steps. In this way, the number of steps and time necessary for manufacturing the organic EL apparatus can be reduced.

### Fifth Embodiment

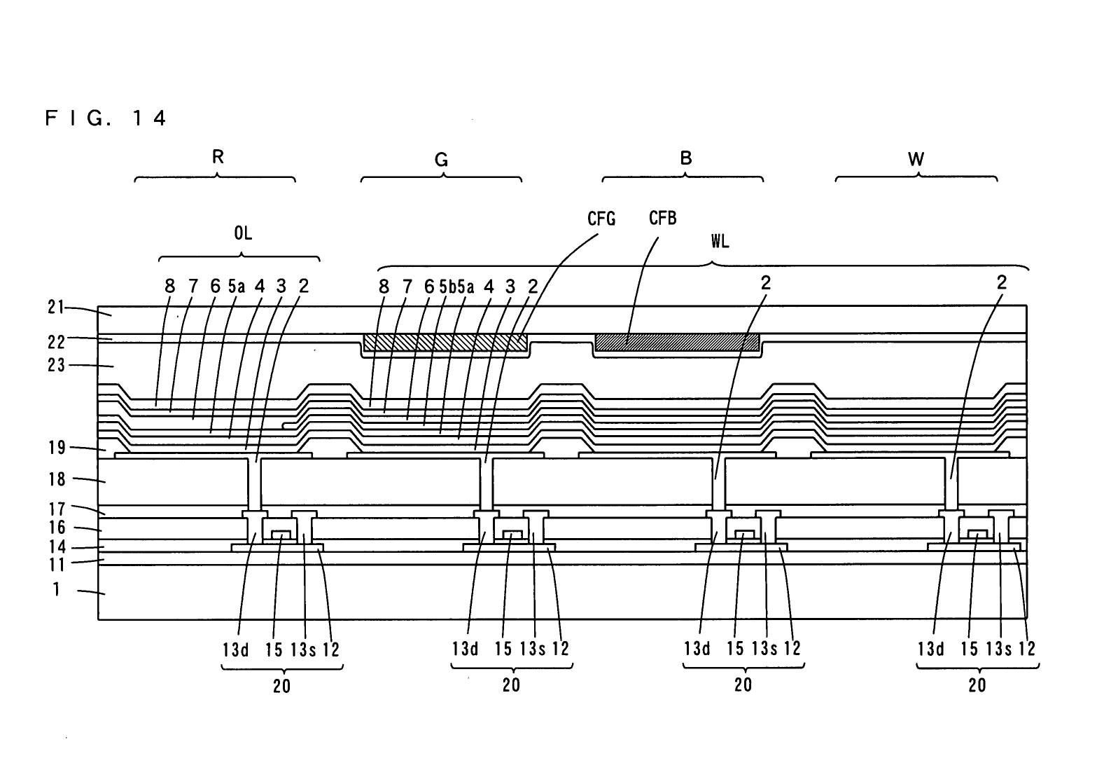

FIG. 14 is a sectional view of an example of the structure of an organic EL apparatus according to a fifth embodiment of the invention.

The structure of the organic EL apparatus in FIG. 14 is different from that of the organic EL apparatus according to the second embodiment (FIG. 7) in that a red color filter layer CFR is not provided.

In this way, in the region R of the organic EL apparatus according to the fifth embodiment, orange light from an organic EL device OL is externally output only through a transparent seal substrate 21.

The organic EL apparatus shown in FIG. 14 has a top emission structure, so that a region on a TFT 20 can be used as a pixel region. More specifically, in the organic EL apparatus shown in FIG. 14, each color filter layer larger than the color filter layer in FIG. 11 can be used. In this way, a wider region can be used as a pixel region, so that the luminance efficiency of the organic EL apparatus further improves.

In this way, according to the embodiment, orange light generated by the organic EL device OL is used as red light among three primary colors. In this way, the luminous efficiency of the organic EL apparatus improves as compared to the case of changing white light from an organic EL device WL into red light using a red color filter layer. Therefore, the power consumption can be reduced.

The organic EL device WL has a common structure for the regions G, B, and W, and therefore the number of steps and time necessary for manufacturing the organic EL apparatus can be reduced.

Orange light emitting layers 5a in the organic EL devices WL and OL can be formed by common steps. In this way, the number of steps and time necessary for manufacturing the organic EL apparatus can be more reduced.

Now, other examples of the organic EL apparatus shown in FIG. 14 having a top emission structure will be described.

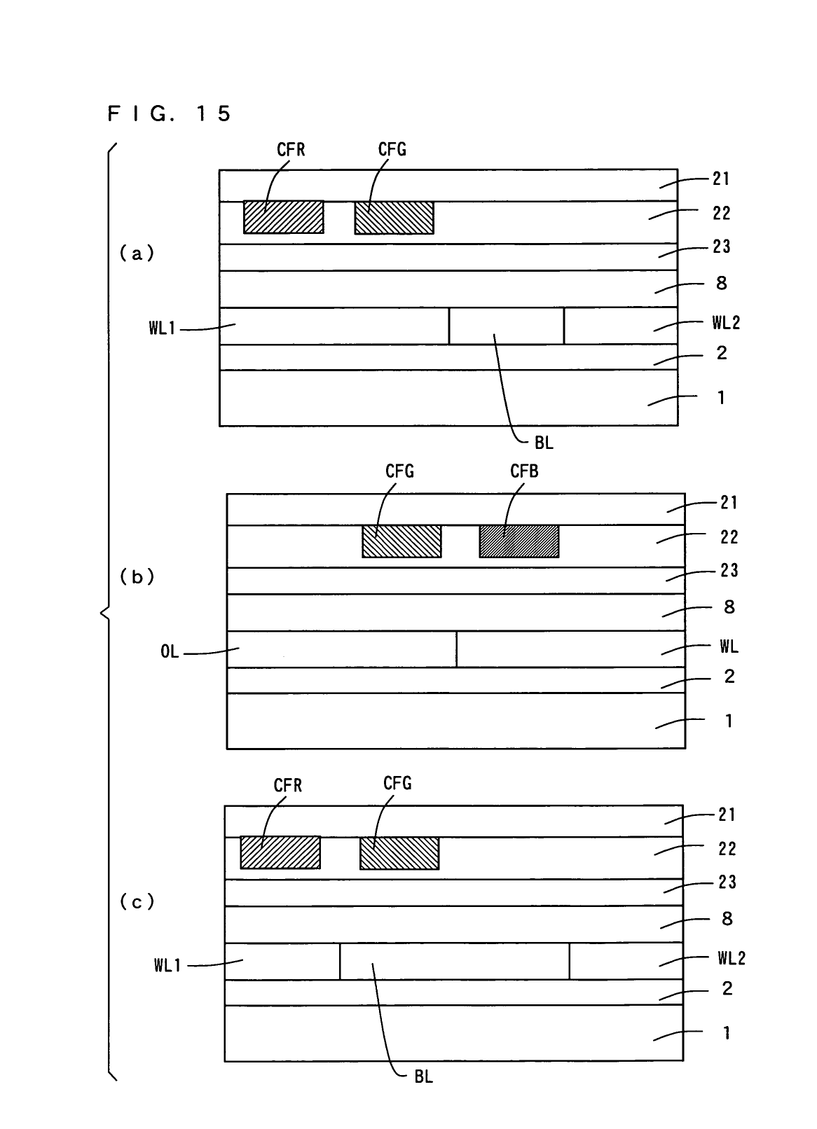

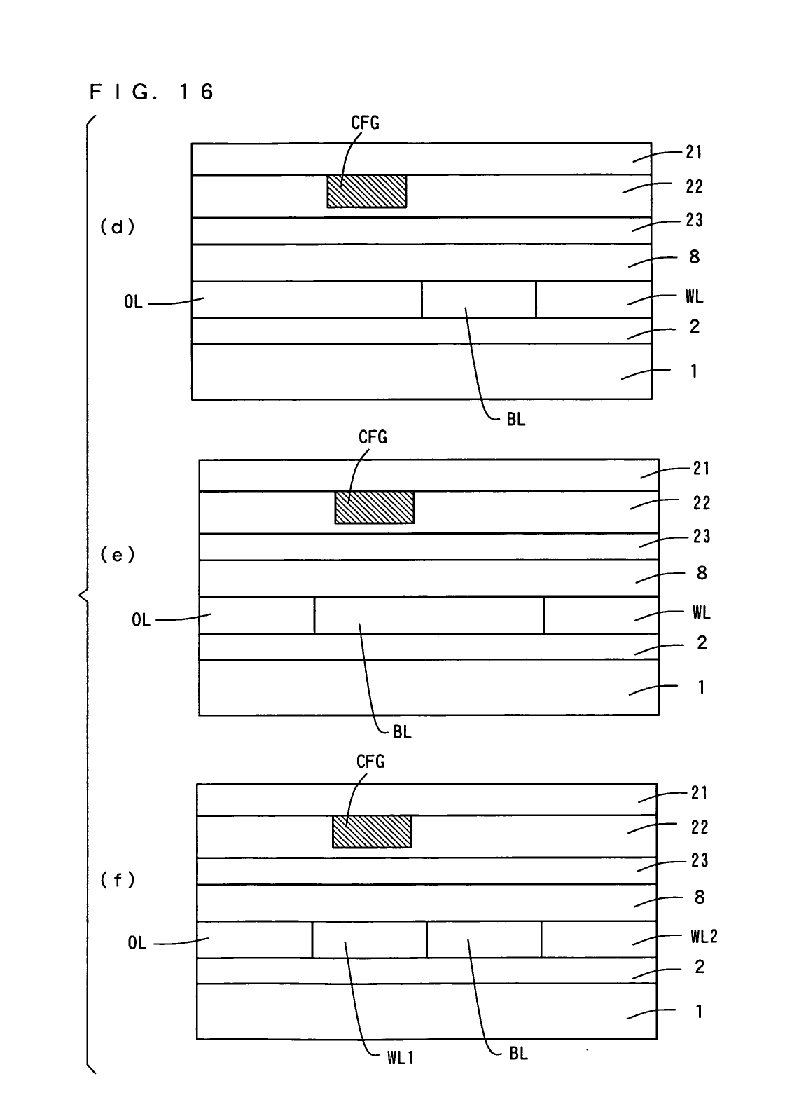

FIGS. 15(a) to 15(c) and 16(d) to 16(f) are views showing the structures of organic EL apparatuses based the modes in Table 1.

FIG. 15(a) is a view showing the structure of an organic EL apparatus based on the second mode in Table 1.

The structure of the organic EL apparatus shown in FIG. 15(a) is different from that of the organic EL apparatus according to the second embodiment (FIG. 8(a)) in that a blue color filter layer CFB is not provided.

In the organic EL apparatus in FIG. 15(a), white light from a first organic EL device WL1 is transmitted through a red color filter layer CFR and a green color filter layer CFG, so that red light and green light can be obtained. Blue light and white light can be obtained from an organic EL device BL and a second organic EL device WL2, respectively. In this way, the luminous efficiency for blue light improves because the blue light is not attenuated.

The organic EL device WL1 has a common structure for the regions R and G, and therefore the number of steps and time necessary for manufacturing the organic EL apparatus can be reduced.

Blue light emitting layers 5b in the organic EL devices WL1(b)L, and WL2 can be formed by common steps. In this way, the number of steps and time necessary for manufacturing the organic EL apparatus can be reduced.

FIG. 15(b) is a view showing the structure of an organic EL apparatus based on the third mode in Table 1.

The structure of the organic EL apparatus shown in FIG. 15(b) is different from that of the organic EL apparatus according to the second embodiment (FIG. 8(b)) in that a red color filter layer CFR is not provided.

In the organic EL apparatus in FIG. 15(b), red light can be obtained from an organic EL device OL, white light from the organic EL device OL is transmitted through a green color filter layer CFG, so that green light can be obtained. White light from an organic EL device WL is transmitted through a blue color filter layer CFB, so that blue light can be obtained and white light can be obtained from the organic EL device WL. In this way, the luminous efficiency for red light improves because the red light is not attenuated.

The organic EL device OL has a common structure for the regions R and G, and therefore the number of steps and time necessary for manufacturing the organic EL apparatus can be reduced.

Orange light emitting layers 5a in the organic EL devices OL and WL can be formed by common steps. In this way, the number of steps and time necessary for manufacturing the organic EL apparatus can be further reduced.

FIG. 15(c) is a view showing the structure of an organic EL apparatus based on the fourth mode in Table 1.

The structure of the organic EL apparatus shown in FIG. 15(c) is different from the structure of the organic EL apparatus according to the second embodiment (FIG. 8(c)) in that a blue color filter layer CFB is not provided.

In the organic EL apparatus in FIG. 15(c), white light from a first organic EL device WL1 is transmitted through a red color filter layer CFR, so that red light can be obtained. Blue light from an organic EL device BL is transmitted through a green color filter layer CFG, so that green light can be obtained and blue light can be obtained from the organic EL device BL. White light can be obtained from a second organic EL device WL2. In this way, the luminous efficiency for blue light improves because the red light is not attenuated.

The organic EL device BL has a common structure for the regions G and B, and therefore the number of steps and time necessary for manufacturing the organic EL apparatus can be reduced.

Blue light emitting layers 5b in the organic EL devices WL1(b)L, and WL2 can be formed by common steps. In this way, the number of steps and time necessary for manufacturing the organic EL apparatus can be further reduced.

With reference to FIGS. 16(d) to 16(f), pattern 1 in each of the fifth to seventh modes in Table 1 will be described by way of illustration.

FIG. 16(d) is a view showing the structure of an organic EL apparatus based on the fifth mode in Table 1.

The structure of the organic EL apparatus shown in FIG. 16(d) is different from that of the organic EL apparatus according to the second embodiment (FIG. 9(d)) in that neither a red color filter layer CFR nor a blue color filter layer CFB is provided.

In the organic EL apparatus in FIG. 16(d), red light can be obtained from an organic EL device OL, and white light from the organic EL device OL is transmitted through a green color filter layer CFG, so that green light can be obtained. Blue light and white light can be obtained from organic EL devices BL and WL, respectively. In this way, the luminous efficiency for red light and blue light improves because the red light and blue light are not attenuated.

The organic EL device OL has a common structure for the regions R and G, and therefore the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be more reduced.

FIG. 16(e) is a view showing the structure of an organic EL apparatus based on the sixth mode in Table 1.

The structure of the organic EL apparatus shown in FIG. 16(e) is different from that of the organic EL apparatus according to the second embodiment (FIG. 9(e)) in that neither a red color filter layer CFR nor a blue color filter layer CFB is provided.

In the organic EL apparatus in FIG. 16(e), red light from an organic EL device OL is transmitted through a green color filter layer CFG, so that green light can be obtained. Blue light can be obtained from an organic EL device BL. White light can be obtained from an organic EL device WL. In this way, the luminous efficiency for red light and blue light improves because the red light and blue light are not attenuated.

The organic EL device BL has a common structure for the regions G and B, and therefore the number of steps and time necessary for manufacturing the organic EL apparatus can be reduced.

Blue light emitting layers 5b in the organic EL devices BL and WL can be formed by common steps. In this way, the number of steps and time necessary for manufacturing the organic EL apparatus can be more reduced.

FIG. 16(f) is a view showing the structure of an organic EL apparatus based on the seventh mode in Table 1.

The structure of the organic EL apparatus shown in FIG. 16(f) is different from that of the organic EL apparatus according to the second embodiment (FIG. 9(f)) in that neither a red color filter layer CFR nor a blue color filter layer CFB is provided.

In the organic EL apparatus in FIG. 16(f), red light can be obtained from an organic EL device OL. White light from a first organic EL device WL1 is transmitted through a green color filter layer CFG, so that green light can be obtained. Blue light can be obtained from an organic EL device BL. White light can be obtained from a second organic EL device WL2. In this way, the luminous efficiency for red light and blue light improves because the red light and blue light are not attenuated.

Orange light emitting layers 5a in the organic EL devices OL and WL1 and blue light emitting layers 5b in the organic EL devices BL and WL2 can be formed by common steps. In this way, the number of steps and time necessary for manufacturing the organic EL apparatus can be reduced.

### Sixth Embodiment

The structure of an organic EL apparatus according to a sixth embodiment of the invention is shown in Table 2. Note that combinations of a plurality of organic EL devices are referred to as “modes” similarly to the above description, and combinations of a plurality of color filter layers in each mode will be referred to as “patterns.” The presence and absence of each of a red color filter layer CFR, a green color filter layer CFG, and a blue color filter layer CFB is indicated by “O” and “x” in Table 2.

TABLE 2

| | 11th mode | 12th mode | 13th mode | 14th mode | 15th mode | | | 16th mode | | | 17th mode | | |
|---|---|---|---|---|---|---|---|---|---|---|---|---|---|
| | (RwGw-Bb) | (Ro-GwBw) | (RoGo-Bw) | (Rw-GbBb) | (RoGo-Bb) | | | (Ro-GbBb) | | | (Ro-Gw-Bb) | | |
| pattern | — | — | — | — | 1 | 2 | 3 | 1 | 2 | 3 | 1 | 2 | 3 |
| CFR | ∘ | x | x | ∘ | x | x | ∘ | x | x | ∘ | x | x | ∘ |
| CFG | ∘ | ∘ | ∘ | ∘ | ∘ | ∘ | ∘ | ∘ | ∘ | ∘ | ∘ | ∘ | ∘ |
| CFB | x | ∘ | ∘ | x | ∘ | x | x | ∘ | x | x | x | ∘ | x |

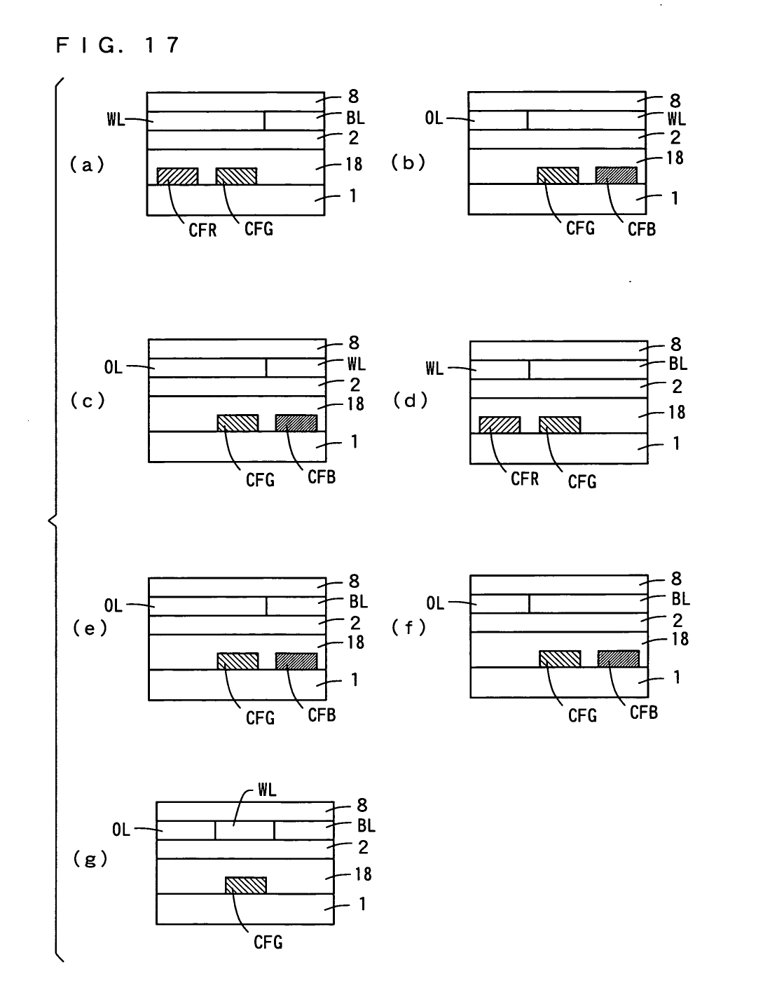

FIGS. 17(a) to 17(g) are views showing the structures of organic EL apparatuses based on the modes in Table 2.

FIG. 17(a) is a view showing the structure of an organic EL apparatus based on the eleventh mode in Table 2.

An organic EL apparatus based on the eleventh mode (RwGw-Bb) can obtain red light and green light based on white light from an organic EL device WL, and blue light from an organic EL device BL that emits blue light.

The structure of the organic EL apparatus shown in FIG. 17(a) is different from the structure of the organic EL apparatus according to the third embodiment (FIG. 10(a)) in that no blue color filter layer CFB is provided.

In the organic EL apparatus in FIG. 17(a), white light from an organic EL device WL is transmitted through a red color filter layer CFR and a green color filter layer CFG, so that red light and green light can be obtained. Blue light can be obtained from an organic EL device BL. In this way, the luminous efficiency for blue light improves because the blue light is not attenuated.

The organic EL device WL has a common structure for the regions R and G, and therefore the number of steps and time necessary for manufacturing the organic EL apparatus can be reduced.

Blue light emitting layers 5b in the organic EL devices WL and BL can be formed by common steps. In this way, the number of steps and time necessary for manufacturing the organic EL apparatus can be further reduced.

FIG. 17(b) is a view showing the structure of an organic EL apparatus based on the twelfth mode in Table 2.

An organic EL apparatus based on the twelfth mode (Ro-GwBw) can obtain red light from an organic EL device OL and green light and blue light from an organic EL device WL.

The structure of the organic EL apparatus shown in FIG. 17(b) is different from that of the organic EL apparatus according to the third embodiment (FIG. 10(b)) in that no red color filter layer CFR is provided.

In the organic EL apparatus in FIG. 17(b), red light can be obtained from the organic EL device OL. White light from the organic EL device WL is transmitted through a green color filter layer CFG and a blue color filter layer CFB, so that green light and blue light can be obtained. In this way, the luminous efficiency for red light improves because the red light is not attenuated.

The organic EL device WL has a common structure for the regions G and B, and therefore the number of steps and time necessary for manufacturing the organic EL apparatus can be reduced.

Orange light emitting layers 5a in the organic EL devices OL and WL can be formed by common steps. In this way, the number of steps and time necessary for manufacturing the organic EL apparatus can be further reduced.

FIG. 17(c) is a view showing the structure of an organic EL apparatus based on the thirteenth mode in Table 2.

The organic EL apparatus based on the thirteenth mode (RoGo-Bw) can obtain red light and green light from an organic EL device OL and blue light from an organic EL device WL.

The structure of the organic EL apparatus shown in FIG. 17(c) is different from the structure of the organic EL apparatus according to the third embodiment (FIG. 10(c)) in that no red color filter layer CFR is provided.

In the organic EL apparatus in FIG. 17(c), red light can be obtained from an organic EL device OL. White light from an organic EL device OL is transmitted through a green color filter layer CFG, so that green light can be obtained. White light from an organic EL device WL is transmitted through a blue color filter layer CFB, so that blue light can be obtained. In this way, the luminous efficiency for red light improves because the red light is not attenuated.

The organic EL device OL has a common structure for the regions R and G, and therefore the number of steps and time necessary for manufacturing the organic EL apparatus can be reduced.

Orange light emitting layers 5a in the organic EL devices OL and WL can be formed by common steps. In this way, the number of steps and time necessary for manufacturing the organic EL apparatus can be further reduced.

FIG. 17(d) is a view showing the structure of an organic EL apparatus based on the fourteenth mode in Table 2.

The organic EL apparatus based on the fourteenth mode (Rw-GbBb) can obtain red light from an organic EL device WL and green light and blue light from an organic EL device BL.

The structure of the organic EL apparatus shown in FIG. 17(d) is different from that of the organic EL apparatus according to the third embodiment (FIG. 10(d)) in that no blue color filter layer CFB is provided.

In the organic EL apparatus in FIG. 17(d), white light from the organic EL device WL is transmitted through a red color filter layer CFR, so that red light can be obtained. Blue light from the organic EL device BL is transmitted through a green color filter layer CFG, so that green light can be obtained. Blue light can be obtained from the organic EL device BL. In this way, the luminous efficiency for blue light improves because the blue light is not attenuated.

The organic EL device BL has a common structure for the regions G and B, and therefore the number of steps and time necessary for manufacturing the organic EL apparatus can be reduced.

Blue light emitting layers 5b in the organic EL devices WL and BL can be formed by common steps. In this way, the number of steps and time necessary for manufacturing the organic EL apparatus can be further reduced.

FIG. 17(e) is a view showing the structure of an organic EL apparatus based on the fifteenth mode in Table 2. Note that in connection with the following fifteenth to seventeenth modes in Table 2, pattern 1 will be described by way of illustration.

The organic EL apparatus based on the fifteenth mode (RoGo-Bb) can obtain red light and green light from an organic EL device OL and blue light from an organic EL device BL.

The structure of the organic EL apparatus shown in FIG. 17(e) is different from that of the organic EL apparatus according to the third embodiment (FIG. 10(e)) in that no red color filter layer CFR is provided.

In the organic EL apparatus in FIG. 17(e), red light can be obtained from an organic EL device OL, and orange light from the organic EL device OL is transmitted through a green color filter layer CFG, so that green light can be obtained. Blue light from an organic EL device BL is transmitted through a blue color filter layer CFB, so that blue light having high chromaticity can be obtained. In this way, the luminous efficiency for red light improves because the red light is not attenuated.

The organic EL device OL has a common structure for the regions R and G, and therefore the number of steps and time necessary for manufacturing the organic EL apparatus can be reduced.

FIG. 17(f) is a view showing the structure of an organic EL apparatus based on the sixteenth mode in Table 2.

An organic EL apparatus based on the sixteenth mode (Ro-GbBb) can obtain red light from an organic EL device OL, and green light and blue light from an organic EL device BL.

The structure of the organic EL apparatus shown in FIG. 17(f) is different from that of the organic EL apparatus according to the third embodiment (FIG. 10(f)) in that no red color filter layer CFR is provided.

In the organic EL apparatus in FIG. 17(f), red light can be obtained from the organic EL device OL. Blue light from the organic EL device BL is transmitted through a green color filter layer CFG and a blue color filter layer CFB, so that green light and blue light that has high chromaticity can be obtained. In this way, the luminous efficiency for red light improves because the red light is not attenuated.

The organic EL device BL has a common structure for the regions G and B, and therefore the number of steps and time necessary for manufacturing the organic EL apparatus can be reduced.

FIG. 17(g) is a view showing the structure of an organic EL apparatus based on the seventeenth mode in Table 2.

The organic EL apparatus based on the seventeenth mode (Ro-Gw-Bb) can obtain red light from an organic EL device OL, green light from an organic EL device WL, and blue light from an organic EL device BL.

The structure of the organic EL apparatus shown in FIG. 17(g) is different from that of the organic EL apparatus according to the third embodiment (FIG. 10(g)) in that neither a red color filter layer CFR nor a blue color filter layer CFB is provided.

In the organic EL apparatus in FIG. 17(g), red light can be obtained from the organic EL device OL. White light from the organic EL device WL is transmitted through a green color filter layer CFG, so that green light can be obtained. Blue light can be obtained from the organic EL device BL. In this way, the luminous efficiency for red light and blue light improves because the red light and blue light are not attenuated.

An orange light emitting layer 5a in the organic EL device OL or a blue light emitting layer 5b in the organic EL device BL and an orange light emitting layer 5a or a blue light emitting layer 5b in the organic EL device WL can be formed by common steps. In this way, the number of steps and time necessary for manufacturing the organic EL apparatus can be more reduced.

Note that the bottom emission type organic EL apparatuses have been described with reference to FIGS. 17(a) to 17(g), but the invention may equally be applied to top emission type organic EL apparatuses.

The organic EL apparatuses according to the above described embodiments are complementary type organic EL apparatuses in which white light is obtained from an orange light emitting layer 5a and a blue light emitting layer 5b, but the invention may equally be applied to primary color type organic EL apparatuses in which white light is obtained from light in three primary colors emitted from three light emitting layers.

### Effects of Fourth to Sixth Embodiments

The organic EL apparatuses according to the above described embodiments each include one of the following arrangements: an arrangement that emits orange light from an organic EL device OL, an arrangement that emits blue light from an organic EL device BL, and an arrangement that emits red light from an organic EL device OL and blue light from an organic EL device BL. In this way, the luminous efficiency for orange light or/and blue light improves. Therefore, the power consumption can be reduced.

How Elements in Claims Correspond to Elements in Embodiments

In the first to third embodiments, the organic EL devices OL, BL, WL, WL1, and WL2 formed in the positions corresponding to the regions R, G, and B in FIG. 1(b) each correspond to any one of first to third organic electroluminescent devices. The red color filter layer CFR, the green color filter layer CFG, and the blue color filter layer CFB each correspond to any one of first to third color changing members.

In the first to third embodiments, red light, green light, and blue light each correspond to light in any one of fourth, fifth, and sixth colors, and white light, orange light, and blue light each correspond to light in any one of first, second, and third colors.

In the fourth to sixth embodiments, the organic EL devices OL, BL, WL, WL1, and WL2 formed in the positions corresponding to the regions R, G, and B in FIG. 1(b) each correspond to any one of first, second, and third organic electroluminescent devices. Green light corresponds to light in a seventh color, and red light and blue light each correspond to light in an eighth or ninth color. The green color filter layer CFG corresponds to a fourth color changing member, and the red color filter layer CFR and the blue color filter layer CFB each correspond to a fifth or sixth color changing member.

### EXAMPLES

Organic EL apparatuses according to inventive examples and comparative examples were produced, and the luminous efficiency of the produced organic EL apparatuses was measured, and the CIE (Commission Internationale d'Eclairage) chromaticity coordinates (x, y) of Inventive Example 1 and Comparative Example 1 were measured.

### Inventive Example 1

In Inventive Example 1, an organic EL apparatus the same as the above described organic EL apparatus shown in FIG. 2 was produced.

The luminous efficiency of the organic EL apparatus according to Inventive Example 1 at 20 mA/cm² was measured. The luminous efficiency was 4.8 cd/A for red light, 9.3 cd/A for green light, and 3.6 cd/A for blue light.

The CIE chromaticity coordinates (x, y) is (0.63, 0.36) for red light, (0.25, 0.56) for green light, and (0.11, 0.21) for blue light.

### Comparative Example 1

The structure of the organic EL apparatus according to Comparative Example 1 is different from that of the organic EL apparatus according to Inventive Example 1 in the following points.

In the organic EL apparatus according to Comparative Example 1, an organic EL device WL is provided instead of an organic EL device OL. A red color filter layer CFR is provided on a second interlayer insulating film 17 in the position corresponding to the region R in FIG. 1(b).

The luminous efficiency of the organic EL apparatus according to Comparative Example 1 at 20 mA/cm² was measured. The luminous efficiency for red light was 2.3 cd/A. The luminous efficiency values for red light and blue light were the same as those for the green light and blue light according to Inventive Example 1.

The CIE chromaticity coordinates (x, y) for red light, green light, and blue light by the organic EL apparatus according to Comparative Example 1 were the same as those for the red light, green light, and blue light according to Inventive Example 1.

Evaluation 1

The luminous efficiency for red light by the organic EL apparatus according to Inventive Example 1 improved to be at least twice the efficiency for red light by the organic EL apparatus according to Comparative Example 1. In this way, it is clearly shown that in the organic EL apparatus according to Inventive Example 1, the luminous efficiency for red light obtained by allowing orange light from the organic EL device OL to pass through a red color filter layer CFR is higher than the luminous efficiency for red light obtained by allowing white light from the organic EL device WL to pass through a red color filter layer CFR.

Consequently, the luminous efficiency of the organic EL apparatus according to Inventive Example 1 is better than that of the organic EL apparatus according to Comparative Example 1.

It was found that in the organic EL apparatus according to Inventive Example 1, red light, green light, and blue light obtained through a red color filter layer CFR, a green color filter layer CFG, and a blue color filter layer CFB, respectively had high purity.

### Inventive Example 2

According to Inventive Example 2, an organic EL apparatus the same as the organic EL apparatus shown in FIG. 11 was produced.

The luminous efficiency of the organic EL apparatus according to Inventive Example 2 at 20 mA/cm² was measured. The luminous efficiency was 12.0 cd/A for red light, 9.3 cd/A for green light, and 3.6 cd/A for blue light.

### Comparative Example 2

The structure of the organic EL apparatus according to Comparative Example 2 is different from that of the organic EL apparatus according to Inventive Example 2 in the following points.

In the organic EL apparatus according to Comparative Example 2, an organic EL device WL is provided instead of an organic EL device OL. A red color filter layer CFR is provided on a second interlayer insulating film 17 in the position corresponding to the region R in FIG. 1(b).

The luminous efficiency of the organic EL apparatus according to Comparative Example 2 at 20 mA/cm² was measured. The luminous efficiency for red light was 2.3 cd/A. The luminous efficiency values for green light and blue light were the same as those for the green light and blue light according to Inventive Example 2.

Evaluation 2

The luminous efficiency for red light in the organic EL apparatus according to Inventive Example 2 improved to be at least five times the luminous efficiency for red light in the organic EL apparatus according to Comparative Example 2. In this way, it was found that in the organic EL apparatus according to Inventive Example 2, the red light was not attenuated.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An organic electroluminescent apparatus, comprising:
a first organic electroluminescent device that generates light in a first color;
a second organic electroluminescent device that generates light in a second color;
a third organic electroluminescent device that generates light in a third color;
a first color changing member that changes light in said first color generated by said first organic electroluminescent device into light in a fourth color;
a second color changing member that changes light in said second color generated by said second organic electroluminescent device into light in a fifth color; and
a third color changing member that changes light in said third color generated by said third organic electroluminescent device into light in a sixth color,
said first color and said fourth color being approximately the same.

2. The organic electroluminescent apparatus according to claim 1, wherein said second color and said fifth color are approximately the same.

3. The organic electroluminescent apparatus according to claim 1, wherein said first color is orange, said second color is white, said third color is white, said fourth color is red, said fifth color is green, and said sixth color is blue.

4. The organic electroluminescent apparatus according to claim 1, wherein said first color is orange, said second color is orange, said third color is white, said fourth color is red, said fifth color is green, and said sixth color is blue.

5. The organic electroluminescent apparatus according to claim 1, wherein said first color is blue, said second color is white, said third color is white, said fourth color is blue, said fifth color is green, and said sixth color is red.

6. The organic electroluminescent apparatus according to claim 1, wherein said first color is blue, said second color is blue, said third color is white, said fourth color is blue, said fifth color is green, and said sixth color is red.

7. The organic electroluminescent apparatus according to claim 2, wherein said first color is orange, said second color is blue, said third color is blue, said fourth color is red, said fifth color is blue, and said sixth color is green.

8. The organic electroluminescent apparatus according to claim 2, wherein said first color is orange, said second color is blue, said third color is orange, said fourth color is red, said fifth color is blue, and said sixth color is green.

9. The organic electroluminescent apparatus according to claim 2, wherein said first color is orange, said second color is blue, said third color is white, said fourth color is red, said fifth color is blue, and said sixth color is green.

10. The organic electroluminescent apparatus according to claim 1, further comprising a substrate, wherein said first, second, and third organic electroluminescent devices are formed on said substrate, and
said first, second, and third color changing members are formed on said first, second, and third organic electroluminescent devices, respectively.

11. The organic electroluminescent apparatus according to claim 1, further comprising a transparent substrate, wherein said first, second, and third color changing members are provided between said transparent substrate and said first, second, and third organic electroluminescent devices, respectively.

12. An organic electroluminescent apparatus, comprising:
a first organic electroluminescent device that generates light in a first color;
a second organic electroluminescent device that generates light in a second color;
a third organic electroluminescent device that generates light in a third color; and
a fourth color changing member that changes light in the second color generated by said second organic electroluminescent device into light in a seventh color,
light generated by at least one of said first and third organic electroluminescent devices being externally output without being passed through the color changing member.

13. The organic electroluminescent apparatus according to claim 12, further comprising a fifth color changing member that changes light in the third color generated by said third organic electroluminescent device into light in an eighth color, wherein light generated by said first organic electroluminescent device is externally output without being passed through any of the color changing members.

14. The organic electroluminescent apparatus according to claim 12, further comprising a sixth color changing member that changes light in the first color generated by the first organic electroluminescent device into light in a ninth color, wherein light generated by said third organic electroluminescent device is externally output without being passed through any of the color changing members.

15. The organic electroluminescent apparatus according to claim 12, wherein light generated by said first and third organic electroluminescent devices are externally output without being passed through any of the color changing members.

16. The organic electroluminescent apparatus according to claim 12, further comprising a substrate, wherein said first to third organic electroluminescent devices are formed on said substrate, and
said color changing member is provided on at least one of said first and third organic electroluminescent devices.

17. The organic electroluminescent apparatus according to claim 12, further comprising a substrate, wherein said color changing member is provided between said substrate and at least one of said first and third organic electroluminescent devices.
